(19) United States
(12) Patent Application Publication
(10) Pub. No.: US 2026/0080926 A1
(43) Pub. Date: Mar. 19, 2026

(54) OPERATION METHOD OF MEMORY DEVICE INCLUDING FERROELECTRIC MEMORY CELL

(71) Applicant: SAMSUNG ELECTRONICS CO., LTD., Suwon-si (KR)

(72) Inventors: YEONJIN LEE, Suwon-si (KR); Ho-Youn KIM, Suwon-si (KR); Haewook JEONG, Suwon-si (KR)

(73) Assignee: SAMSUNG ELECTRONICS CO., LTD., Suwon-si (KR)

(21) Appl. No.: 19/196,351

(22) Filed: May 1, 2025

(30) Foreign Application Priority Data
Sep. 13, 2024 (KR) 10-2024-0125306

(51) Int. Cl. G11C 11/22

(52) U.S. Cl. CPC G11C 11/2273; G11C 11/2255; G11C 11/2257; G11C 11/2259

(57) ABSTRACT

Disclosed is an operation method of a memory device which includes a ferroelectric memory cell. The method includes: receiving a read command and an address from a controller; and performing a read operation on a ferroelectric memory cell corresponding to the address, based on a first read mode or a second read mode, according to the read command. In the first read mode, a first read voltage is applied as an across voltage of a ferroelectric capacitor included in the ferroelectric memory cell. In the second read mode, a second read voltage is applied as the across voltage of the ferroelectric capacitor included in the ferroelectric memory cell. The first read voltage and the second read voltage have opposite polarities.

### CROSS-REFERENCE TO RELATED APPLICATION

This application claims priority to Korean Patent Application No. 10-2024-0125306, filed on Sep. 13, 2024, in the Korean Intellectual Property Office, the disclosure of which is incorporated by reference herein in its entirety.

### BACKGROUND

The present disclosure relates to a semiconductor memory, and more particularly, to an operation method of a memory device including a ferroelectric memory cell.

A semiconductor memory may be classified as a volatile memory, which loses data stored therein when a power is turned off, such as a static random access memory (SRAM) or a dynamic random access memory (DRAM), or a nonvolatile memory, which retains data stored therein even when a power is turned off, such as a flash memory, a phase-change RAM (PRAM), a magnetic RAM (MRAM), a resistive RAM (RRAM), or a ferroelectric RAM (FRAM).

A ferroelectric memory may be a nonvolatile memory which is similar in structure to the DRAM but maintains data by using a ferroelectric capacitor regardless of whether a power is supplied. For example, a ferroelectric RAM may include a plurality of memory cells, and each of the plurality of memory cells may include a ferroelectric capacitor. A polarization state of the ferroelectric capacitor may be controlled by adjusting a voltage across the ferroelectric capacitor. Data stored in a memory cell may be determined depending on the polarization state of the ferroelectric capacitor, and the polarization state of the ferroelectric capacitor may be maintained even though a power is turned off.

### SUMMARY

One or more example embodiments provide an operation method of a memory device including a ferroelectric memory cell with improved reliability.

According to an aspect of an example embodiment, a method of operating a memory device, includes: receiving a read command and an address from a controller; and performing a read operation on a ferroelectric memory cell corresponding to the address, based on a first read mode or a second read mode, according to the read command. In the first read mode, a first read voltage is applied as an across voltage of a ferroelectric capacitor included in the ferroelectric memory cell. In the second read mode, a second read voltage is applied as the across voltage of the ferroelectric capacitor included in the ferroelectric memory cell. The first read voltage and the second read voltage have opposite polarities.

According to another aspect of an example embodiment, a method of operating a memory device which includes a plurality of ferroelectric memory cells, includes: receiving a first read command and a first address from a controller; reading data by performing a first read operation on a first ferroelectric memory cell corresponding to the first address from among the plurality of ferroelectric memory cells based on a first read voltage according to the first read command, and outputting the data to the controller; receiving a second read command and the first address from the controller; and reading the data by performing a second read operation on the first ferroelectric memory cell corresponding to the first address based on a second read voltage according to the second read command, and outputting the data to the controller. A polarity of the first read voltage is different than a polarity of the second read voltage.

According to another aspect of an example embodiment, a method of operating a memory device which includes a ferroelectric memory cell, includes: performing a first read operation on the ferroelectric memory cell based on a first read mode; changing a read mode of the memory device from the first read mode to a second read mode; and performing a second read operation on the ferroelectric memory cell based on the second read mode. The first read operation includes applying a first read voltage as an across voltage of a ferroelectric capacitor included in the ferroelectric memory cell. The second read operation includes applying a second read voltage as the across voltage of the ferroelectric capacitor included in the ferroelectric memory cell. The first read voltage and the second read voltage have opposite polarities.

According to another aspect of an example embodiment, a method of operating a memory device which includes a ferroelectric memory cell, includes: receiving a first read command including information about a first read mode from a controller; performing a first read operation on the ferroelectric memory cell based on the first read mode, according to the first read command; receiving a second read command including information about a second read mode from the controller; and performing a second read operation on the ferroelectric memory cell based on the second read mode according to the second read command. The first read operation includes applying a first read voltage as an across voltage of a ferroelectric capacitor included in the ferroelectric memory cell. The second read operation includes applying a second read voltage as the across voltage of the ferroelectric capacitor included in the ferroelectric memory cell. The first read voltage and the second read voltage have opposite polarities.

According to another aspect of an example embodiment, a method of operating a memory device which includes a ferroelectric memory cell, includes: applying a first read voltage to the ferroelectric memory cell to perform a first read operation of reading data; and applying a second read voltage to the ferroelectric memory cell to perform a second read operation of reading the data. The first read operation and the second read operation on the ferroelectric memory cell are performed in turn. The first read voltage and the second read voltage have opposite polarities.

According to another aspect of an example embodiment, a ferroelectric memory device includes: a ferroelectric memory cell connected to a word line, a bit line and a plate line; a dummy memory cell connected to the word line, and configured to store information about a read mode of the ferroelectric memory cell; and a controller configured to: based on the read mode being a first read mode, control a first read voltage to be applied to the ferroelectric memory cell in a read operation on the ferroelectric memory cell; and based on the read mode being a second read mode, control a second read voltage to be applied to the ferroelectric memory cell in the read operation on the ferroelectric memory cell. The first read voltage and the second read voltage have opposite polarities.

### BRIEF DESCRIPTION OF THE FIGURES

The above and other aspects and features will be more apparent from the following description of example embodiments, taken in conjunction with the accompanying drawings, in which:

FIG. 1 is a block diagram illustrating a memory device according to an example embodiment.

FIG. 2 is a diagram illustrating a memory cell included in a memory cell array according to an example embodiment.

FIGS. 3A, 3B and 3C are diagrams for describing a write operation on a memory cell according to an example embodiment.

FIG. 4 is a diagram for describing an imprint phenomenon of a memory cell.

FIG. 5 is a flowchart illustrating an operation of a memory device according to an example embodiment.

FIG. 6 is a diagram for describing an operation of a memory device according to an example embodiment.

FIGS. 7A, 7B, 8A and 8B are diagrams for describing a read operation according to an example embodiment.

FIGS. 9A, 9B, 10A and 10B are diagrams for describing a rewrite operation according to an example embodiment.

FIGS. 11A and 11B are timing diagrams for describing an operation of a memory device according to an example embodiment.

FIG. 12 is a diagram for describing a read operation based on a second read mode according to an example embodiment.

FIG. 13 is a flowchart illustrating an operation of a memory device according to an example embodiment.

FIG. 14 is a diagram for describing an operation according to a second read mode according to an example embodiment.

FIG. 15 is a block diagram illustrating a memory device performing an operation according to an example embodiment.

FIG. 16 is a diagram for describing first and second read modes of a memory device according to an example embodiment.

FIG. 17 is a block diagram illustrating a memory system according to an example embodiment.

FIG. 18 is a flowchart illustrating an operation of a memory device according to an example embodiment.

FIG. 19 is a flowchart illustrating an operation of a memory device according to an example embodiment.

FIG. 20 is a flowchart illustrating an operation of a memory device according to an example embodiment.

FIG. 21 is a flowchart illustrating an operation of a memory device according to an example embodiment.

FIGS. 22A and 22B are diagrams for describing an operation of a memory device according to an example embodiment.

FIGS. 23A and 23B are diagrams for describing an operation of a memory device according to an example embodiment.

FIG. 24 is a flowchart illustrating an operation of a memory device according to an example embodiment.

FIG. 25 is a block diagram illustrating a memory system according to an example embodiment.

FIG. 26 is a diagram illustrating a system according to an example embodiment.

### DETAILED DESCRIPTION

Hereinafter, example embodiments are described in detail with reference to the accompanying drawings. Like components are denoted by like reference numerals throughout the specification, and repeated descriptions thereof are omitted. Embodiments described herein are example embodiments, and thus, the present disclosure is not limited thereto, and may be realized in various other forms. Each example embodiment provided in the following description is not excluded from being associated with one or more features of another example or another embodiment also provided herein or not provided herein but consistent with the present disclosure.

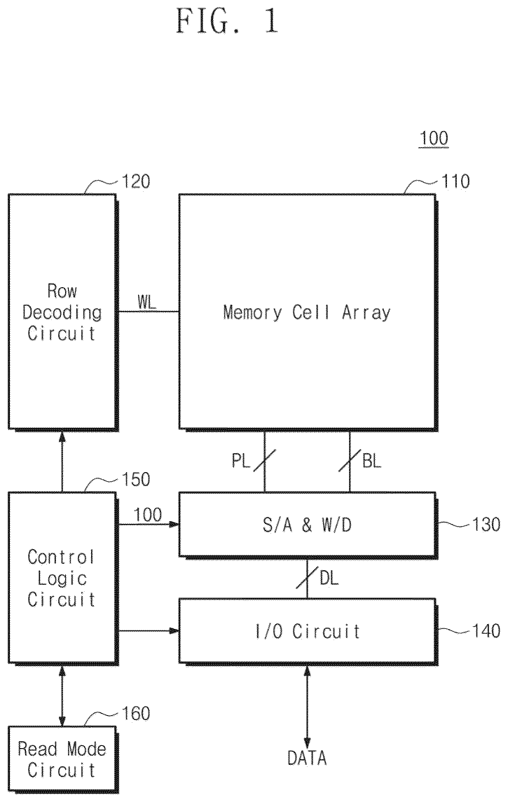

FIG. 1 is a block diagram illustrating a memory device according to an example embodiment. Referring to FIG. 1, a memory device 100 may include a memory cell array 110, a row decoding circuit 120, a sense amplifier/write driver 130, an input/output circuit 140, and a control logic circuit 150. Under control of an external device (e.g., a controller), the memory device 100 may store data or may output the stored data.

The memory cell array 110 may include a plurality of memory cells. The plurality of memory cells may be arranged in rows and columns. The plurality of memory cells may be connected to word lines WL, plate lines PL, and bit lines BL. For example, memory cells located at the same row from among the plurality of memory cells may be connected to the same word line. Memory cells located at the same column from among the plurality of memory cells may be connected to the same plate line and the same bit line. However, the above arrangement of the memory cells is provided as an example, and the present disclosure is not limited thereto.

The row decoding circuit 120 may be connected to the memory cell array 110 through the word lines WL. The row decoding circuit 120 may control voltages of the word lines WL under control of the control logic circuit 150. In an example embodiment, the row decoding circuit 120 may decode a row address received from the external device (e.g., a controller) and may control voltages of the word lines WL based on a decoding result.

The sense amplifier/write driver 130 may be connected to the memory cell array 110 through the plate lines PL and the bit lines BL. The sense amplifier/write driver 130 may receive data “DATA” from the input/output circuit 140 through data lines DL and may control voltages of the plate lines PL and the bit lines BL based on the received data “DATA”. The sense amplifier/write driver 130 may sense voltage changes of the bit lines BL and may read data stored in the memory cell array 110 based on the sensed voltage changes.

The input/output circuit 140 may exchange the data “DATA” with the external device (e.g., a controller). The input/output circuit 140 may transfer the data “DATA” to the sense amplifier/write driver 130 through the data lines DL or may receive the read data “DATA”from the sense amplifier/write driver 130 through the data lines DL.

The control logic circuit 150 may control all the operations of the memory device 100. For example, the control logic circuit 150 may control the row decoding circuit 120, the sense amplifier/write driver 130, and the input/output circuit 140 such that the memory device 100 performs the read operation or the write operation.

In an example embodiment, each of the plurality of memory cells included in the memory cell array 110 may be a ferroelectric memory cell. For example, the ferroelectric memory cell may include a ferroelectric capacitor. A polarization state or a polarization value of the ferroelectric capacitor may vary depending on a voltage across the ferroelectric capacitor; even though the voltage across the ferroelectric capacitor is blocked, the ferroelectric capacitor has the characteristic that the polarization state or the polarization value is maintained. That is, the ferroelectric memory cell has a characteristic of a nonvolatile memory, that is, the characteristic that information or data corresponding to the polarization state or the polarization value of the ferroelectric capacitor are capable of being maintained during a given time.

In an example embodiment, the memory device 100 may apply the read voltage across the ferroelectric capacitor of the ferroelectric memory cell and may read a state (i.e., a data bit) of the ferroelectric memory cell. In this case, when the read voltage of the same polarity (e.g., +) is repeatedly or continuously applied across the ferroelectric capacitor, a ferroelectric material may exhibit an imprint phenomenon, thereby causing the degradation of the ferroelectric memory cell.

According to an example embodiment, the memory device 100 may further include a read mode circuit 160. The read mode circuit 160 may store or manage information about a read mode of the memory device 100. For example, the memory device 100 may operate in a first read mode or a second read mode based on the information stored in the read mode circuit 160. In the first read mode, the memory device 100 may apply a first read voltage across the ferroelectric capacitor and may perform the read operation on ferroelectric memory cells. In the second read mode, the memory device 100 may apply a second read voltage across the ferroelectric capacitor and may perform the read operation on ferroelectric memory cells. For example, the polarity of the first read voltage may be opposite to the polarity of the second read voltage. That is, when the first read voltage is a negative voltage, the second read voltage may be a positive voltage. The first and second read voltages having opposite polarities may be alternately applied across the ferroelectric capacitor, and the imprint phenomenon of the ferroelectric material may be prevented. Accordingly, the reliability of the ferroelectric memory cells may be improved. The operation of the memory device 100 according to an example embodiment will be described in detail with reference to the following drawings.

The memory device 100 described with reference to FIG. 1 is provided as an example, and example embodiments are not limited thereto. The memory device 100 may further include a command buffer, an address buffer, etc. depending on a way to implement the memory device 100. In an example embodiment, the memory device 100 may be similar in architecture to the DRAM device and may communicate with the external device based on an interface (e.g., a DDR interface or an LPDDR interface) of the DRAM device. Alternatively, the memory device 100 may communicate with the external device (e.g., a CPU or an AP) through various different interfaces, for example, an Advanced Technology Attachment (ATA) interface, a Serial ATA (SATA) interface, an external SATA (e-SATA) interface, a Small Computer Small Interface (SCSI) interface, a Serial Attached SCSI (SAS) interface, a Peripheral Component Interconnection (PCI) interface, a PCI express (PCIe) interface, NVM express (NVMe) interface, an IEEE 1394 interface, a Universal Serial Bus (USB) interface, a Secure Digital (SD) card interface, a Multi-Media Card (MMC) interface, an embedded Multi-Media Card (eMMC) interface, a Universal Flash Storage (UFS) interface, an embedded Universal Flash Storage (eUFS) interface, and/or a Compact Flash (CF) card interface.

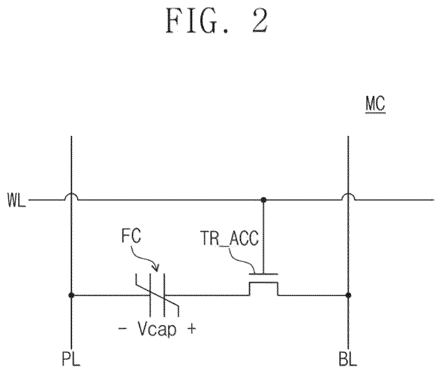

FIG. 2 is a diagram illustrating a memory cell included in a memory cell array of FIG. 1. One memory cell MC will be described with reference to FIG. 2. However, the present disclosure is not limited thereto. For example, each of the plurality of memory cells included in the memory cell array 110 may be similar in structure to the memory cell MC of FIG. 2.

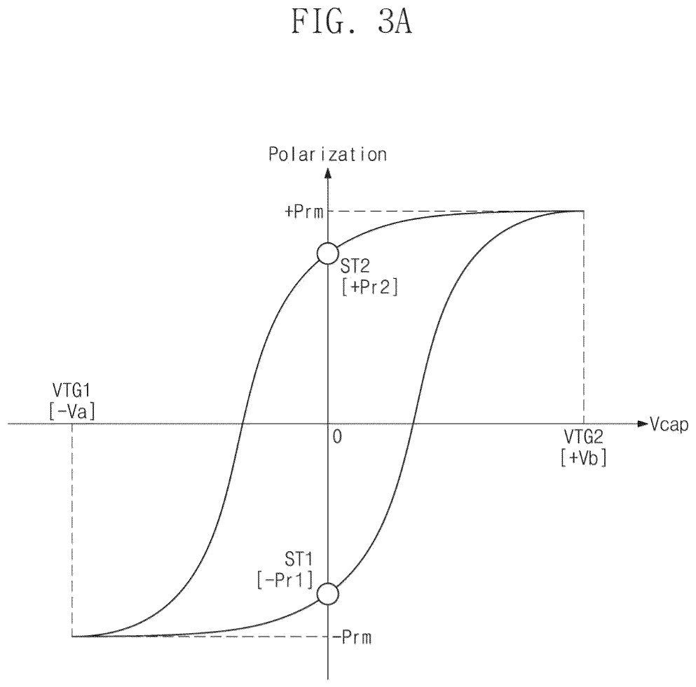

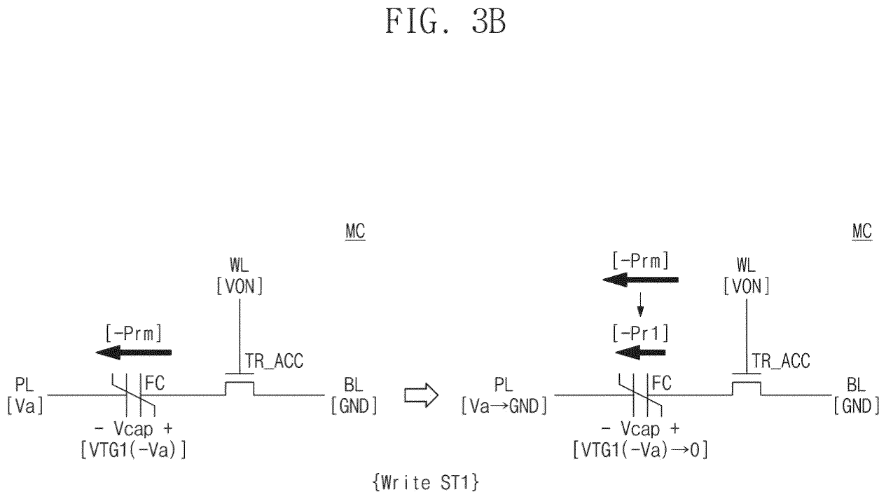

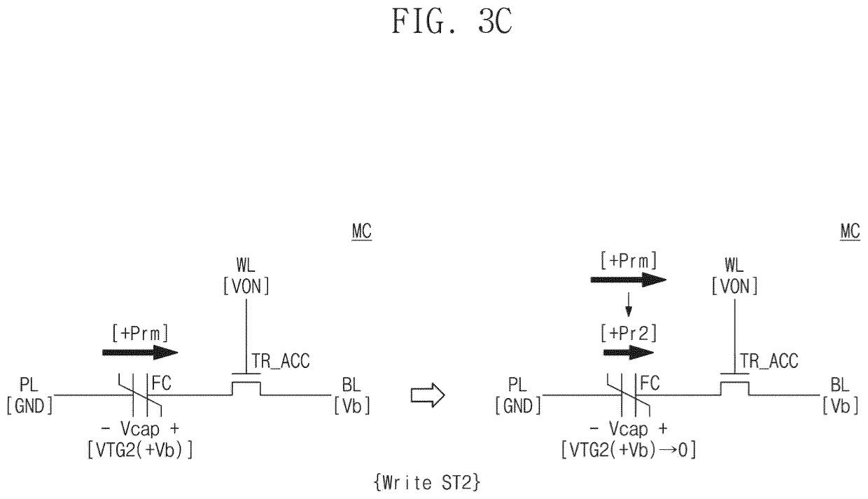

Referring to FIGS. 1 and 2, the memory cell MC may include an access transistor TR_ACC and a ferroelectric capacitor FC. The access transistor TR_ACC may be connected between the ferroelectric capacitor FC and the bit line BL. A gate of the access transistor TR_ACC may be connected to the word line WL. The access transistor TR may operate in response to a voltage of the word line WL. For example, when a turn-on voltage VON (refer to FIG. 3B) is applied to the word line WL, the access transistor TR_ACC may be turned on, and thus, the ferroelectric capacitor FC may be electrically connected to the bit line BL.

The ferroelectric capacitor FC may be connected between the plate line PL and the access transistor TR_ACC. The ferroelectric capacitor FC may include a ferroelectric material, an antiferroelectric material, a paraelectric material, or a dielectric layer formed of a combination thereof. In an example embodiment, the ferroelectric material may include a perovskite material such as BaTiOx, a hafnium (Hf)-based fluoride material, and an HfxZr1-xOy material. The antiferroelectric material may include materials such as ZrO2, HfxZr1-xOy, PbZrO3, and NaNbO3. The ferroelectric or antiferroelectric material may be a hafnium (Hf)-based fluoride material or may include a La-based rare earth element in an HfxZr1-xOy material. The ferroelectric or antiferroelectric material may include hafnium oxide. The paraelectric material may include high dielectric materials such as BeO2, MaO2, CaO2, SrO2, Al2O3, Y2O3, Sc2O3, La2O3, HfO2, ZrO2, TiO2, Ta2O5, Nb2O5, V2O5, SrTiO3, and BaSrTiO3.

In an example embodiment, the ferroelectric capacitor FC may include a dielectric layer formed of a ferroelectric material. In this case, the polarization state or the polarization value of the ferroelectric capacitor FC may vary depending on an across voltage Vcap. Moreover, even when the voltage Vcap is blocked, the ferroelectric capacitor FC may maintain the polarization state or the polarization value during a given time. The polarization state or the polarization value of the ferroelectric capacitor FC may be set or adjusted differently depending on data or information to be stored in the memory cell MC; in this case, a plurality of data or a plurality of information may be stored in the memory cell MC.

FIGS. 3A to 3C are diagrams for describing a write operation on a memory cell of FIG. 2. In the example embodiment, in the graph of FIG. 3A, the horizontal axis represents the across voltage Vcap of the ferroelectric capacitor FC, and the vertical axis represents the polarization state or the polarization value of the ferroelectric capacitor FC.

For convenience of description, it is assumed that the memory cell MC is a memory cell including the ferroelectric capacitor FC described with reference to FIG. 2. The polarization state of the ferroelectric capacitor FC may be indicated by a negative number or a positive number; in this case, it may be understood that the negative number or the positive number of the polarization state indicates the directionality of the polarization state of the ferroelectric capacitor FC.

Below, for convenience, the description will be given as the polarization state of the ferroelectric capacitor FC is symmetrical with respect to the across voltage Vcap. In this case, when the across voltage Vcap is 0 V, the polarization state of the ferroelectric capacitor FC may be stabilized. However, the present disclosure is not limited thereto. For example, the polarization state of the ferroelectric capacitor FC may be asymmetrical with respect to the across voltage Vcap; in this case, at the across voltage Vcap which is not 0 V, the polarization state of the ferroelectric capacitor FC may be stabilized.

Referring to FIGS. 2, 3A, 3B, and 3C, as illustrated in FIG. 3A, the polarization state of the ferroelectric capacitor FC included in the memory cell MC may change depending on the across voltage Vcap. In this case, the polarization state of the ferroelectric capacitor FC has a hysteresis characteristic according to the across voltage Vcap. Accordingly, in a state where the across voltage Vcap is 0 V, the polarization state of the ferroelectric capacitor FC may be set to a first state ST1 or a second state ST2.

As an example, a first target voltage VTG1 may be applied as the across voltage Vcap of the ferroelectric capacitor FC, and then, the across voltage Vcap of the ferroelectric capacitor FC may change from the first target voltage VTG1 to 0 V. In this case, the polarization state of the ferroelectric capacitor FC may be set to a first polarization state −Pr1 (or the first state ST1).

For example, as illustrated in FIG. 3B, the turn-on voltage VON may be applied to the word line WL of the memory cell MC, an a-th voltage Va may be applied to the plate line PL, and a ground voltage GND may be applied to the bit line BL. The across voltage Vcap of the ferroelectric capacitor FC is a difference between the voltage of the bit line BL and the voltage of the plate line PL (i.e., is (VBL-VPL)). In this case, the across voltage Vcap may be −Va, and −Va may correspond to the first target voltage VTG1. According to the above condition, the polarization state of the ferroelectric capacitor FC may change to a negative saturation polarization state −Prm.

The voltage of the plate line PL may then change from the a-th voltage Va to the ground voltage GND. In this case, the across voltage Vcap may change from the first target voltage VTG1 to 0 V. Accordingly, the polarization state of the ferroelectric capacitor FC may change from the negative saturation polarization state −Prm to the first polarization state −Pr1 along the hysteresis curve of FIG. 3A. The polarization state of the ferroelectric capacitor FC being the first polarization state −Pr1 may correspond to the memory cell MC having the first state ST1.

As an example, a second target voltage VTG2 may be applied as the across voltage Vcap of the ferroelectric capacitor FC, and then, the across voltage Vcap of the ferroelectric capacitor FC may change from the second target voltage VTG2 to 0 V. In this case, the polarization state of the ferroelectric capacitor FC may be set to a second polarization state +Pr2 (or the second state ST2).

For example, as illustrated in FIG. 3C, the turn-on voltage VON may be applied to the word line WL of the memory cell MC, the ground voltage GND may be applied to the plate line PL, and a b-th voltage Vb may be applied to the bit line BL. In this case, the across voltage Vcap of the ferroelectric capacitor FC may be +Vb, and +Vb may correspond to the second target voltage VTG2. According to the above condition, the polarization state of the ferroelectric capacitor FC may change to a positive saturation polarization state +Prm.

The voltage of the bit line BL may then change from the b-th voltage Vb to the ground voltage GND. In this case, the across voltage Vcap may change from the second target voltage VTG2 to 0 V. Accordingly, the polarization state of the ferroelectric capacitor FC may change from the positive saturation polarization state +Prm to the second polarization state −Pr2 along the hysteresis curve of FIG. 3A. The polarization state of the ferroelectric capacitor FC being the second polarization state+Pr2 may correspond to the memory cell MC having the second state ST2.

As described above, the memory device 100 may differently set the polarization state or a remanent polarization state of the ferroelectric capacitor FC by using the hysteresis characteristic of the ferroelectric capacitor FC. Accordingly, it may be possible to store desired information or data bits in memory cells each including the ferroelectric capacitor FC.

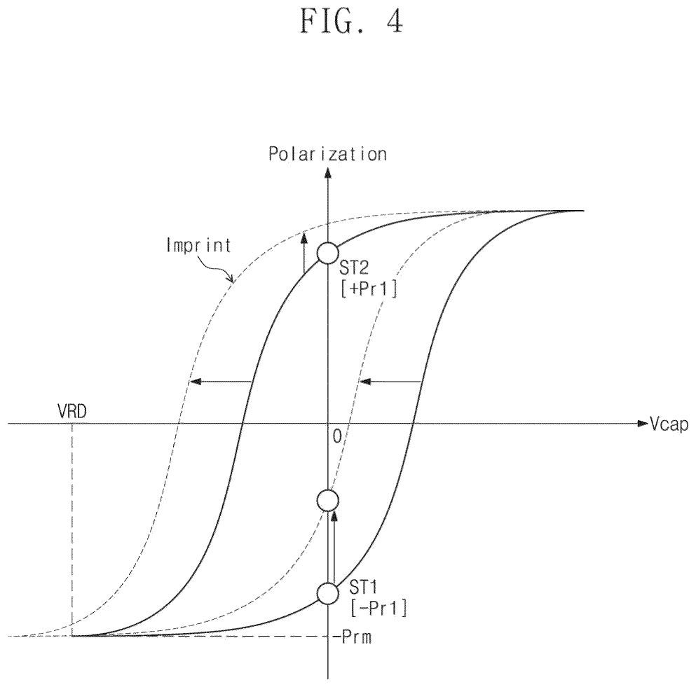

FIG. 4 is a diagram for describing an imprint phenomenon of a memory cell of FIG. 2. In FIG. 4, the horizontal axis represents the across voltage Vcap of the ferroelectric capacitor FC, and the vertical axis represents the polarization state of the ferroelectric capacitor FC.

As described with reference to FIGS. 3A to 3C, the memory device 100 may perform the write operation on memory cells by differently setting the polarization state of the ferroelectric capacitor FC. The memory device 100 may apply a read voltage VRD as the across voltage Vcap of the ferroelectric capacitor FC and may determine states of memory cells (i.e., may read data stored in the memory cells).

For example, the memory device 100 may apply the read voltage VRD as the across voltage Vcap of the ferroelectric capacitor FC. In this case, the polarization state of the ferroelectric capacitor FC, and the voltage of the bit line BL or the plate line PL may differently change depending on a change amount or a change direction of the polarization state. The memory device 100 may determine the state of the memory cell MC (i.e., may read data stored in the memory cell MC) by sensing the voltage change of the bit line BL or the plate line PL.

In an example embodiment, when the memory device 100 repeatedly perform the read operation on the memory cell MC by using a read voltage (e.g., VRD) of the same polarity, remanent charges may be accumulated in the ferroelectric capacitor FC of the memory cell MC. In this case, the hysteresis curve of the ferroelectric capacitor FC may shift in a specific direction, resulting in an imprint phenomenon. As illustrated in FIG. 4, when the ferroelectric capacitor FC experiences the imprint, the polarization state of the ferroelectric capacitor FC may not have an intended state (e.g., −Pr1 or +Pr2). In this case, the state of the memory cell MC may not be determined normally, thereby causing the reduction of reliability of the memory device 100.

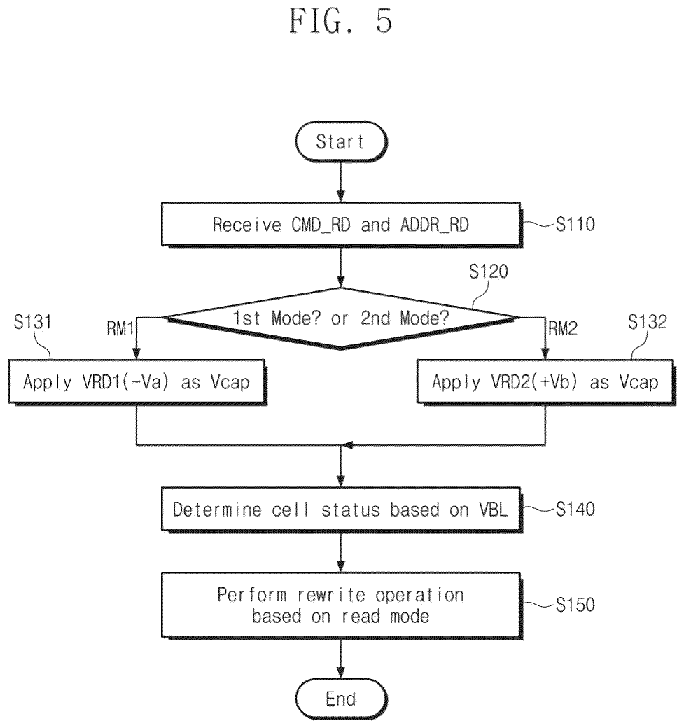

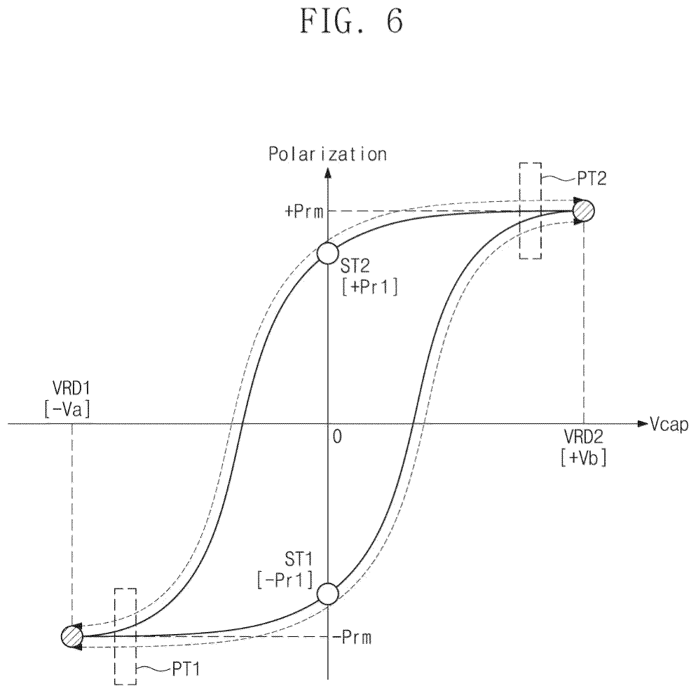

FIG. 5 is a flowchart illustrating an operation of a memory device of FIG. 1. FIG. 6 is a diagram for describing an operation of a memory device according to the flowchart of FIG. 5. In the graph of FIG. 6, the horizontal axis represents the across voltage Vcap of the ferroelectric capacitor FC, and the vertical axis represents the polarization state of the ferroelectric capacitor FC.

Below, for convenience, the description will be given as the memory device 100 performs the read operation on one memory cell MC. However, the present disclosure is not limited thereto. For example, the memory device 100 may perform the read operations on a plurality of memory cells simultaneously or in parallel. In an example embodiment, a plurality of memory cells may be connected to the same word line.

Referring to FIGS. 1, 2, 5, and 6, in operation S110, the memory device 100 may receive a read command CMD_RD and a read address ADDR_RD. For example, the memory device 100 may receive the read command CMD_RD and the read address ADDR_RD from the external device (e.g., a controller, a CPU, or an AP). In an example embodiment, in operation S120 to operation S150, the memory device 100 may perform the read operation on memory cells corresponding to the read address ADDR_RD in response to the read command Cmd_RD.

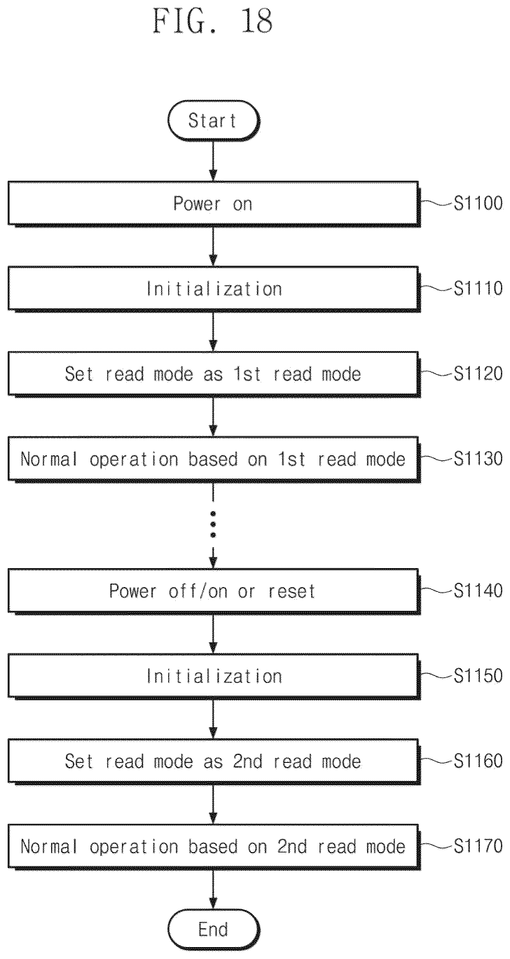

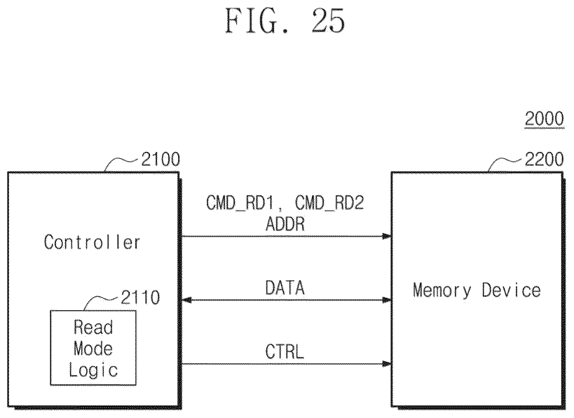

In operation S120, the memory device 100 may determine the read mode. For example, the memory device 100 may select one of a first read mode RM1 and a second read mode RM2, based on information stored in the read mode circuit 160. In an example embodiment, the read mode circuit 160 may manage the read mode, based on an operating time or an operation count of the memory device 100. In an example embodiment, the read mode circuit 160 may manage the read mode individually in units of memory cell, in units of word line, in units of codeword, in units of data block, in units of cache line, or in units of sub-array. In an example embodiment, the read mode circuit 160 may change the read mode depending on various conditions. How to manage the read mode will be described in detail with reference to FIGS. 18 and 25.

When the read mode is the first read mode RM1, in operation S131, the memory device 100 may apply a first read voltage VRD1 as the across voltage Vcap of the ferroelectric capacitor FC of the memory cell MC. The first read voltage VRD1 may be −Va (or a negative voltage). In this case, as illustrated in FIG. 6, the polarization state of the ferroelectric capacitor FC may change to the negative saturation polarization state −Prm along a first path PT1.

When the read mode is the second read mode RM2, in operation S132, the memory device 100 may apply a second read voltage VRD2 as the across voltage Vcap of the ferroelectric capacitor FC of the memory cell MC. The second read voltage VRD2 may be +Vb (or a positive voltage). In this case, as illustrated in FIG. 6, the polarization state of the ferroelectric capacitor FC may change to the positive saturation polarization state +Prm along a second path PT2.

In operation S140, the memory device 100 may determine the state (e.g., ST1 or ST2) of the memory cell MC, based on a bit line voltage VBL. For example, when the polarization state of the ferroelectric capacitor FC is changed through operation S131 or operation S132, the magnitude of the bit line voltage VBL may vary depending on a change magnitude of the polarization state or a direction change of the polarization state. The memory device 100 may detect the bit line voltage VBL or the change amount of the bit line voltage VBL and may determine the state (e.g., ST1 or ST2) of the memory cell MC. In an example embodiment, the memory device 100 may output a data bit or read data to the external device (e.g., a controller, an AP, or a CPU) based on the determined state of the memory cell MC.

In operation S150, the memory device 100 may perform a rewrite operation on the memory cell MC based on the read mode. For example, through operation S131 or operation S132, the polarization state of the ferroelectric capacitor FC of the memory cell MC may have the negative saturation polarization state —Prm or the positive saturation polarization state +Prm. The negative saturation polarization state −Prm or the positive saturation polarization state +Prm may be different from the original state (e.g., −Pr1 or +Pr2) of the memory cell MC. Accordingly, the memory device 100 may perform the rewrite operation such that the polarization state of the ferroelectric capacitor FC of the memory cell MC has the original state (e.g., −Pr1 or +Pr2). In an example embodiment, based on the read mode, the memory device 100 may control a plate line voltage VPL or the bit line voltage VBL to perform the rewrite operation.

As described above, the memory device 100 according to an example embodiment may apply the first read voltage VRD1 as the across voltage Vcap of the ferroelectric capacitor FC in the first read mode RM1 and may apply the second read voltage VRD2 as the across voltage Vcap of the ferroelectric capacitor FC in the second read mode RM2. That is, in the read operation on the memory cell MC, the imprint phenomenon of the ferroelectric capacitor FC may be prevented by applying the first read voltage VRD1 and the second read voltage VRD2 in turn.

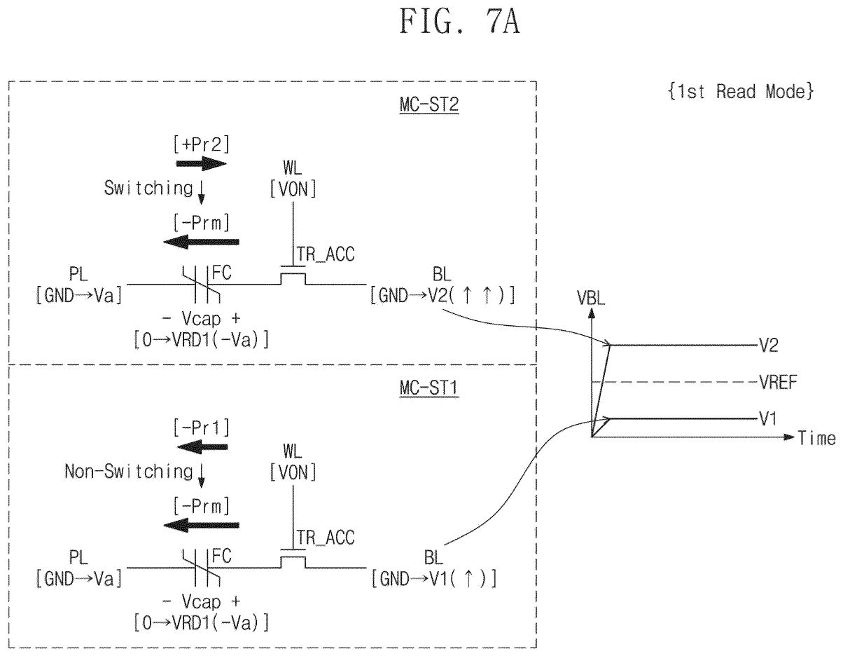

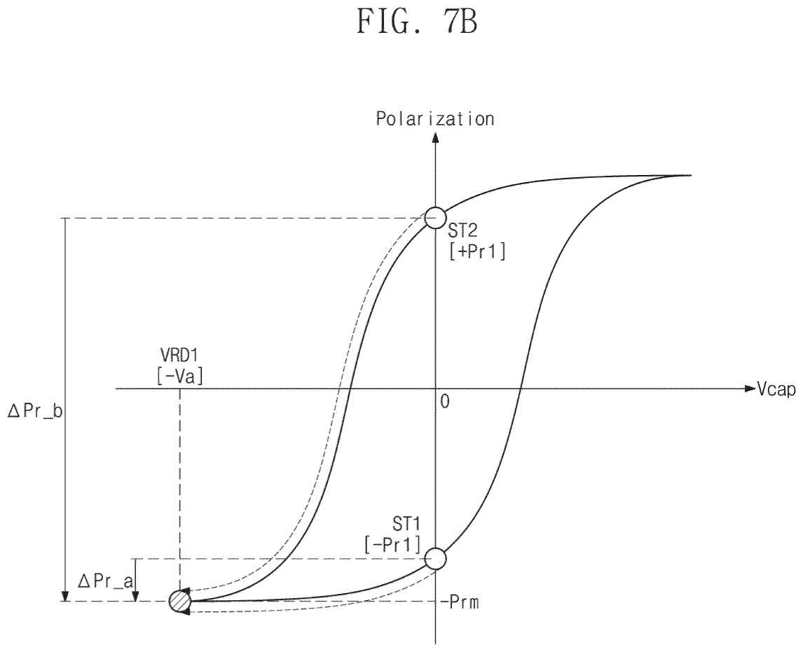

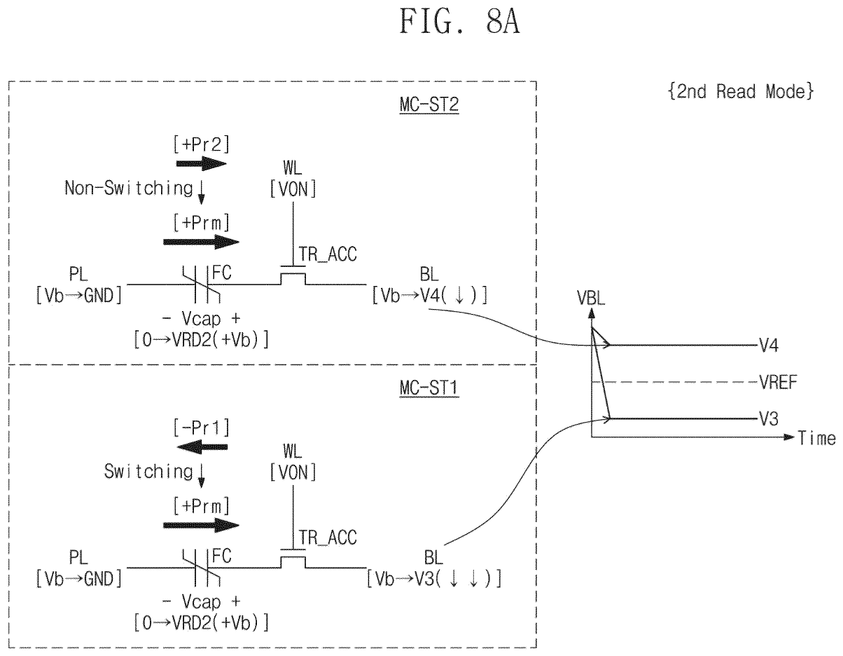

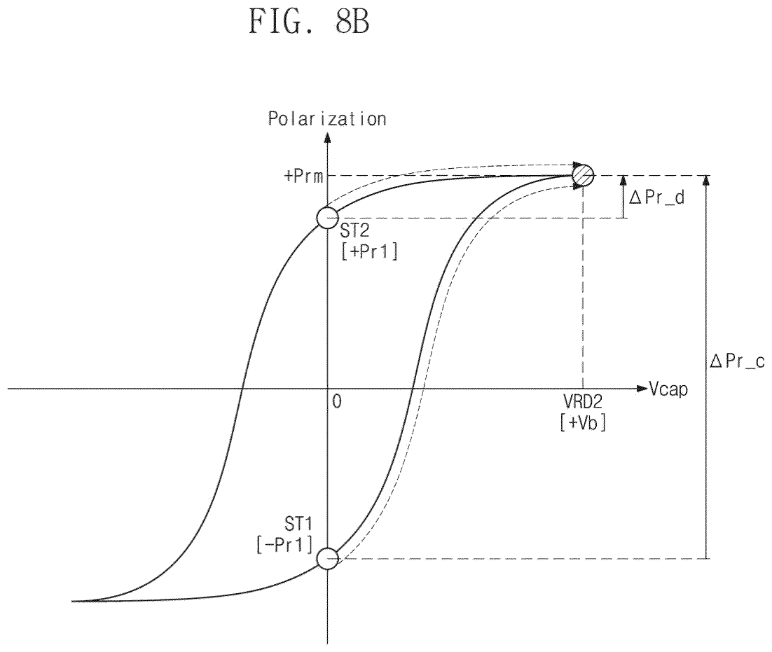

FIGS. 7A to 8B are diagrams for describing a read operation according to the flowchart of FIG. 5. The read operation according to the first read mode RM1 will be described with reference to FIGS. 7A and 7B, and the read operation according to the second read mode RM2 will be described with reference to FIGS. 8A and 8B. Below, for convenience of description, a memory cell having the first state ST1 is referred to as a “first state memory cell MC-ST1”, and a memory cell having the second state ST2 is referred to as a “second state memory cell MC-ST2”. The first and second state memory cells MC-ST1 and MC-ST2 may be distinguished from each other depending on the polarization state of the ferroelectric capacitor FC, and the first and second state memory cells MC-ST1 and MC-ST2 do not indicate different memory cells or memory cells physically distinguished from each other.

First, referring to FIGS. 1, 2, 5, 7A, and 7B, the memory device 100 may perform the read operation on the memory cell MC based on the first read mode RM1. In an example embodiment, the first read mode RM1 may indicate a read mode in which the first read voltage VRD1 is applied as the across voltage Vcap of the ferroelectric capacitor FC. The first read voltage VRD1 may be a voltage of −Va (e.g., a negative voltage).

For example, as illustrated in FIG. 7A, the plate line PL and the bit line BL of the first state memory cell MC-ST1 may maintain the ground voltage GND. In this case, the across voltage Vcap of the ferroelectric capacitor FC of the first state memory cell MC-ST1 may be 0 V, and the ferroelectric capacitor FC of the first state memory cell MC-ST1 may have the first polarization state −Pr1. In the first read mode RM1, the memory device 100 may change the voltage of the plate line PL from the ground voltage GND to the a-th voltage Va. In this case, the across voltage Vcap of the ferroelectric capacitor FC may change from 0 V to −Va. −Va may correspond to the first read voltage VRD1. As illustrated in FIG. 7B, in response to the across voltage Vcap being the first read voltage VRD1, the first polarization state −Pr1 of the ferroelectric capacitor FC of the first state memory cell MC-ST1 may change to the negative saturation polarization state −Prm. As the polarization state of the ferroelectric capacitor FC of the first state memory cell MC-ST1 is changed, the bit line voltage VBL may change from the ground voltage GND to a first voltage V1.

Likewise, the plate line PL and the bit line BL of the second state memory cell MC-ST2 may maintain the ground voltage GND. In this case, the across voltage Vcap of the ferroelectric capacitor FC of the second state memory cell MC-ST2 may be 0 V, and the ferroelectric capacitor FC of the second state memory cell MC-ST2 may have the second polarization state +Pr2. In the first read mode RM1, the memory device 100 may change the voltage of the plate line PL from the ground voltage GND to the a-th voltage Va. In this case, the across voltage Vcap of the ferroelectric capacitor FC may change from 0 V to −Va. −Va may correspond to the first read voltage VRD1. As illustrated in FIG. 7B, in response to the across voltage Vcap being the first read voltage VRD1, the second polarization state+Pr2 of the ferroelectric capacitor FC of the second state memory cell MC-ST2 may change to the negative saturation polarization state −Prm. As the polarization state of the ferroelectric capacitor FC of the second state memory cell MC-ST2 is changed, the bit line voltage VBL may change from the ground voltage GND to a second voltage V2.

In an example embodiment, the change amount of the bit line voltage VBL may correspond to a change amount of the polarization state of the ferroelectric capacitor FC or whether the polarization state is switched (or changed). For example, in the first read mode RM1, the polarization state of the first state memory cell MC-ST1 may change from the first polarization state −Pr1 to the negative saturation polarization state −Prm; in this case, the change amount of the polarization state may be ΔPr_a, and the polarization state is not switched (or changed). In the first read mode RM1, the polarization state of the second state memory cell MC-ST2 may change from the second polarization state+Pr2 to the negative saturation polarization state −Prm; in this case, the change amount of the polarization state may be ΔPr_b, and the polarization state is switched (or changed). That is, ΔPr_b is greater than ΔPr_a. That is, in the first read mode RM1, the change amount (or the increment) of the bit line voltage VBL associated with the second state memory cell MC-ST2 is greater than the change amount (or the increment) of the bit line voltage VBL associated with the first state memory cell MC-ST1. In this regard, the second voltage V2 may be higher than the first voltage V1.

In the first read mode RM1, the sense amplifier/write driver 130 of the memory device 100 may determine that the memory cell MC is in the second state ST2 when the bit line voltage VBL is higher than a reference voltage VREF and may determine that the memory cell MC is in the first state ST1 when the bit line voltage VBL is lower than the reference voltage VREF.

Next, referring to FIGS. 1, 2, 5, 8A, and 8B, the memory device 100 may perform the read operation on the memory cell MC based on the second read mode RM2. In an example embodiment, the second read mode RM2 may indicate a read mode in which the second read voltage VRD2 is applied as the across voltage Vcap of the ferroelectric capacitor FC. The second read voltage VRD2 may be a voltage of +Va (e.g., a positive voltage).

For example, as illustrated in FIGS. 8A and 8B, the plate line PL and the bit line BL of the first state memory cell MC-ST1 may maintain the b-th voltage Vb. In this case, the across voltage Vcap of the ferroelectric capacitor FC of the first state memory cell MC-ST1 may be 0 V, and the ferroelectric capacitor FC of the first state memory cell MC-ST1 may have the first polarization state −Pr1. In the second read mode RM2, the memory device 100 may change the voltage of the plate line PL from the b-th voltage Vb to the ground voltage GND. In this case, the across voltage Vcap of the ferroelectric capacitor FC may change from 0 V to +Vb. +Vb may correspond to the second read voltage VRD2. As illustrated in FIG. 8B, in response to the across voltage Vcap being the second read voltage VRD2, the first polarization state −Pr1 of the ferroelectric capacitor FC of the first state memory cell MC-ST1 may change to the positive saturation polarization state +Prm. As the polarization state of the ferroelectric capacitor FC of the first state memory cell MC-ST1 is changed, the bit line voltage VBL may change from the b-th voltage Vb to a third voltage V3.

Likewise, the plate line PL and the bit line BL of the second state memory cell MC-ST2 may maintain the b-th voltage Vb. In this case, the across voltage Vcap of the ferroelectric capacitor FC of the second state memory cell MC-ST2 may be 0 V, and the ferroelectric capacitor FC of the second state memory cell MC-ST2 may have the second polarization state +Pr2. In the second read mode RM2, the memory device 100 may change the voltage of the plate line PL from the b-th voltage Vb to the ground voltage GND. In this case, the across voltage Vcap of the ferroelectric capacitor FC may change from 0 V to +Vb. +Vb may correspond to the second read voltage VRD2. As illustrated in FIG. 8B, in response to the across voltage Vcap being the second read voltage VRD2, the second polarization state+Pr2 of the ferroelectric capacitor FC of the second state memory cell MC-ST2 may change to the positive saturation polarization state +Prm. As the polarization state of the ferroelectric capacitor FC of the second state memory cell MC-ST2 is changed, the bit line voltage VBL may change from the b-th voltage Vb to a fourth voltage V4.

In an example embodiment, the change amount (or the decrement) of the bit line voltage VBL may correspond to a change amount of the polarization state or whether the polarization state is switched (or changed). For example, in the second read mode RM2, the polarization state of the first state memory cell MC-ST1 may change from the first polarization state −Pr1 to the positive saturation polarization state+ Prm; in this case, the change amount of the polarization state may be ΔPr_c, and the polarization state is switched (or changed). In the second read mode RM2, the polarization state of the second state memory cell MC-ST2 may change from the second polarization state+ Pr2 to the positive saturation polarization state+ Prm; in this case, the change amount of the polarization state may be ΔPr_d, and the polarization state is not switched (or changed). That is, ΔPr_c is greater than ΔPr_d. That is, in the second read mode RM2, the change amount (or the decrement) of the bit line voltage VBL associated with the first state memory cell MC-ST1 is greater than the change amount (or the decrement) of the bit line voltage VBL associated with the second state memory cell MC-ST2. In this regard, the third voltage V3 may be lower than the fourth voltage V4.

In the second read mode RM2, the sense amplifier/write driver 130 of the memory device 100 may determine that the memory cell MC is in the second state ST2 when the bit line voltage VBL is higher than the reference voltage VREF and may determine that the memory cell MC is in the first state ST1 when the bit line voltage VBL is lower than the reference voltage VREF.

As described above, the memory device 100 according to an example embodiment may apply the first read voltage VRD1 as the across voltage Vcap of the ferroelectric capacitor FC in the first read mode RM1 and may apply the second read voltage VRD2 as the across voltage Vcap of the ferroelectric capacitor FC in the second read mode RM2. For example, in the first read mode RM1, the memory device 100 may apply the ground voltage GND to the plate line PL and the bit line BL and may then apply the a-th voltage Va to the plate line PL. The memory device 100 may compare the bit line voltage VBL with the reference voltage VREF to determine the state of the memory cell MC. In the second read mode RM2, the memory device 100 may apply the b-th voltage Vb to the plate line PL and the bit line BL and may then apply the ground voltage GND to the plate line PL. The memory device 100 may compare the bit line voltage VBL with the reference voltage VREF to determine the state of the memory cell MC.

As described above, because the memory device 100 performs the read operation by using read voltages with different polarities (e.g., VRD1 and VRD2) depending on read modes (e.g., RM1 and RM2), the imprint phenomenon of the ferroelectric capacitor FC may be prevented.

In an example embodiment, the polarization state of the ferroelectric capacitor FC of the first state memory cell MC-ST1 may not be switched in the first read mode RM1 (this may be referred to as “non-switching”) and may be switched in the second read mode RM2 (this may be referred to as “switching”). The polarization state of the ferroelectric capacitor FC of the second state memory cell MC-ST2 may be switched in the first read mode RM1 (this may be referred to as “switching”) and may not be switched in the second read mode RM2 (this may be referred to as “non-switching”). That is, the polarization state of the ferroelectric capacitor of the memory cell in the same state may be switched or may not be switched, depending on the read mode.

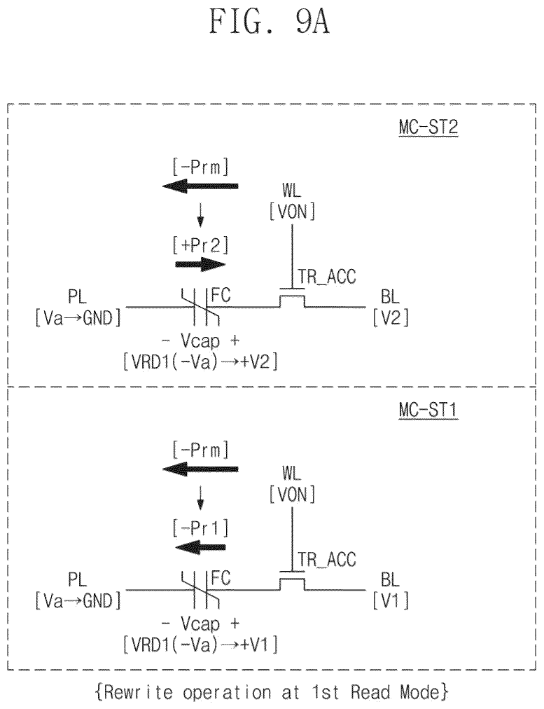

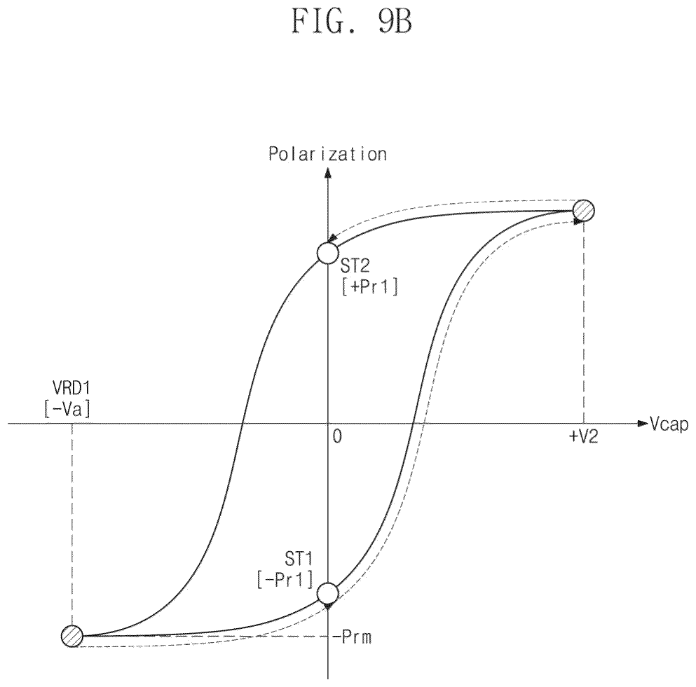

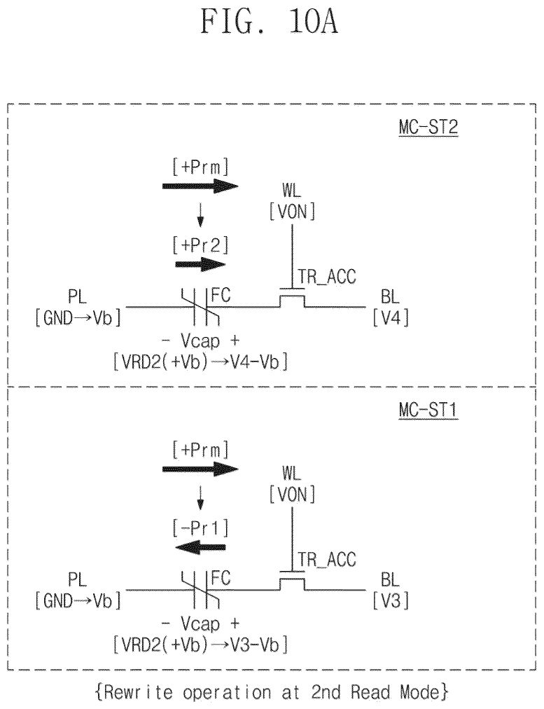

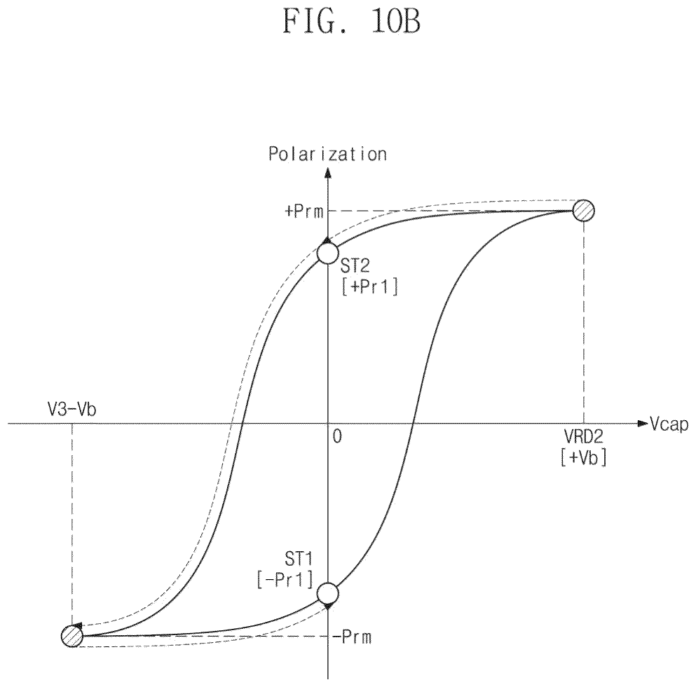

FIGS. 9A to 10B are diagrams for describing a rewrite operation according to the flowchart of FIG. 5. The rewrite operation according to the first read mode RM1 will be described with reference to FIGS. 9A and 9B, and the rewrite operation according to the second read mode RM2 will be described with reference to FIGS. 10A and 10B.

First, referring to FIGS. 1, 2, 5, 9A, and 9B, in the first read mode RM1, the first read voltage VRD1 (−Va) may be applied as the across voltage Vcap of the ferroelectric capacitor FC of the first state memory cell MC-ST1, and thus, the ferroelectric capacitor FC may have the negative saturation polarization state −Prm, and the bit line BL may have the first voltage V1. In this case, the memory device 100 may change the voltage of the plate line PL from the a-th voltage Va to the ground voltage GND, and thus the across voltage Vcap of the ferroelectric capacitor FC may change from −Va to +V1. In an example embodiment, +V1 may be 0 V or may be a voltage close to 0 V. In this case, as illustrated in FIG. 9B, as the across voltage Vcap of the ferroelectric capacitor FC is changed from −Va to +V1, the polarization state of the ferroelectric capacitor FC may be switched from the negative saturation polarization state −Prm to the first polarization state −Pr1. Accordingly, the first state memory cell MC-ST1 may have the first state ST1.

Likewise, in the first read mode RM1, the first read voltage VRD1 (−Va) may be applied as the across voltage Vcap of the ferroelectric capacitor FC of the second state memory cell MC-ST2, and thus, the ferroelectric capacitor FC may have the negative saturation polarization state −Prm, and the bit line BL may have the second voltage V2. In this case, the memory device 100 may change the voltage of the plate line PL from the a-th voltage Va to the ground voltage GND, and thus the across voltage Vcap of the ferroelectric capacitor FC may change from −Va to +V2. In an example embodiment, +V2 may be the second target voltage VTG2 (or +Vb) or may be a voltage close to the second target voltage VTG2 (or +Vb). In this case, as illustrated in FIG. 9B, as the across voltage Vcap of the ferroelectric capacitor FC is changed from −Va to +V2, the polarization state of the ferroelectric capacitor FC may be switched from the negative saturation polarization state −Prm to the positive saturation polarization state +Prm. The memory device 100 may then apply the ground voltage GND to the plate line PL and the bit line BL, and thus, the polarization state of the ferroelectric capacitor FC may be the second polarization state +Pr2. Accordingly, the second state memory cell MC-ST2 may have the second state ST2.

Next, referring to FIGS. 1, 2, 5, and 10A, and 10B, in the second read mode RM2, the second read voltage VRD2 (+Vb) may be applied as the across voltage Vcap of the ferroelectric capacitor FC of the first state memory cell MC-ST1, and thus, the ferroelectric capacitor FC may have the positive saturation polarization state +Prm, and the bit line BL may have the third voltage V3. In this case, the memory device 100 may change the voltage of the plate line PL from the ground voltage GND to the b-th voltage Vb, and thus the across voltage Vcap of the ferroelectric capacitor FC may change from +Vb to (+V3−Vb). In an example embodiment, (+V3−Vb) may correspond to the first target voltage VTG1 or may be a level close to the first target voltage VTG1. In this case, as illustrated in FIG. 10B, as the across voltage Vcap of the ferroelectric capacitor FC is changed from +Vb to (V3−Vb), the polarization state of the ferroelectric capacitor FC may be switched from the positive saturation polarization state +Prm to the negative saturation polarization state −Prm. The memory device 100 may then apply the ground voltage GND to the plate line PL and the bit line BL, and thus, the polarization state of the ferroelectric capacitor FC may be the first polarization state −Pr1. Accordingly, the first state memory cell MC-ST1 may have the first state ST1.

Likewise, in the second read mode RM2, the second read voltage VRD2 (+Vb) may be applied as the across voltage Vcap of the ferroelectric capacitor FC of the second state memory cell MC-ST2, and thus, the ferroelectric capacitor FC may have the positive saturation polarization state+Prm, and the bit line BL may have the fourth voltage V4. In this case, the memory device 100 may change the voltage of the plate line PL from the ground voltage GND to the b-th voltage Vb, and thus the across voltage Vcap of the ferroelectric capacitor FC may change from +Vb to (+V4−Vb). In an example embodiment, (V4−Vb) may be 0V or may be a voltage close to 0 V. In this case, as illustrated in FIG. 10B, as the across voltage Vcap of the ferroelectric capacitor FC is changed from +Vb to (V4−Vb), the polarization state of the ferroelectric capacitor FC may be switched from the positive saturation polarization state +Prm to the second polarization state +Pr2. Accordingly, the second state memory cell MC-ST2 may have the second state ST2.

As described above, depending on the read mode, the memory device 100 may perform the read operation on the memory cell MC and may then perform the rewrite operation on the memory cell MC. When the read operation is performed based on the first read mode RM1, the memory device 100 may perform the rewrite operation on the memory cell MC by changing the voltage of the plate line PL to the ground voltage GND. Alternatively, when the read operation is performed based on the second read mode RM2, the memory device 100 may perform the rewrite operation on the memory cell MC by changing the voltage of the plate line PL to the b-th voltage Vb.

In an example embodiment, in the rewrite operation of the memory device 100, the bit line voltage VBL connected to the memory cell MC is illustrated as having the first to fourth voltages V1 to V4, but the present disclosure is not limited thereto. For example, each of the first to fourth voltages V1 to V4 may be a voltage level corresponding to a polarization state change of the ferroelectric capacitor FC described with reference to FIGS. 7A to 8B. Alternatively, each of the first to fourth voltages V1 to V4 may be a level amplified by the sense amplifier/write driver 130 of the memory device 100.

For example, the first voltage V1 may indicate a level of the bit line voltage VBL by the first state memory cell MC-ST1 in the first read mode RM1, and the second voltage V2 may indicate a level of the bit line voltage VBL by the second state memory cell MC-ST2 in the first read mode RM1. In this case, the sense amplifier/write driver 130 may decrease the first voltage V1 of the bit line BL to the ground voltage GND and may increase the second voltage V2 of the bit line BL to the b-th voltage Vb. In this case, assuming that the rewrite operation is performed in the first read mode RM1, when the ground voltage GND is applied to the plate line PL, the across voltage Vcap of the ferroelectric capacitor FC of the first state memory cell MC-ST1 may be 0 V, and the across voltage Vcap of the ferroelectric capacitor FC of the second state memory cell MC-ST2 may be the second target voltage VTG2. Accordingly, the first state memory cell MC-ST1 may be rewritten to have the first state ST1, and the second state memory cell MC-ST2 may be rewritten to have the second state ST2.

Likewise, the third voltage V3 may indicate a level of the bit line voltage VBL by the first state memory cell MC-ST1 in the second read mode RM2, and the fourth voltage V4 may indicate a level of the bit line voltage VBL by the second state memory cell MC-ST2 in the second read mode RM2. In this case, the sense amplifier/write driver 130 may decrease the third voltage V3 of the bit line BL to the ground voltage GND and may increase the fourth voltage V4 of the bit line BL to the a-th voltage Va. In this case, assuming that the rewrite operation is performed in the second read mode RM2, when the b-th voltage Vb is applied to the plate line PL, the across voltage Vcap of the ferroelectric capacitor FC of the first state memory cell MC-ST1 may be −Vb, and the across voltage Vcap of the ferroelectric capacitor FC of the second state memory cell MC-ST2 may be (Va−Vb) (e.g., 0 V). Accordingly, the first state memory cell MC-ST1 may be rewritten to have the first state ST1, and the second state memory cell MC-ST2 may be rewritten to have the second state ST2.

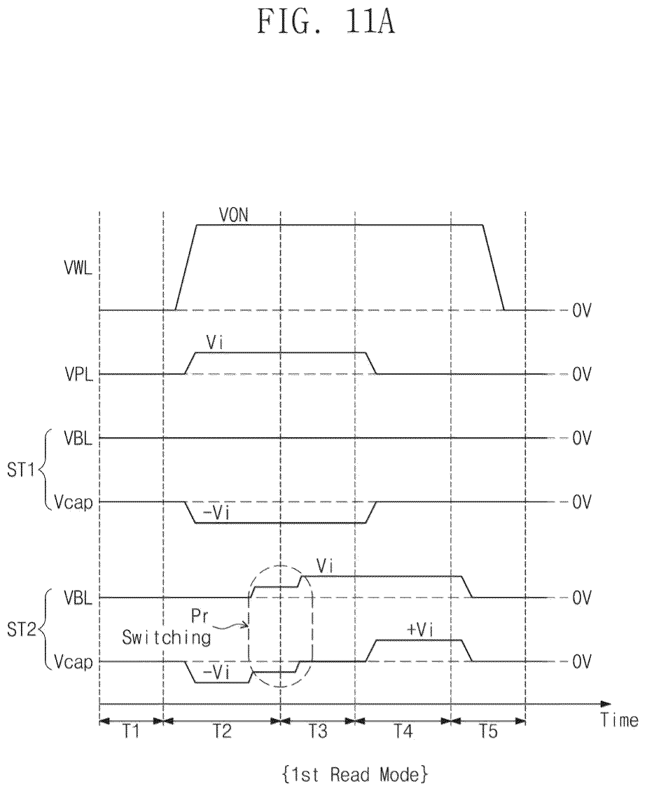

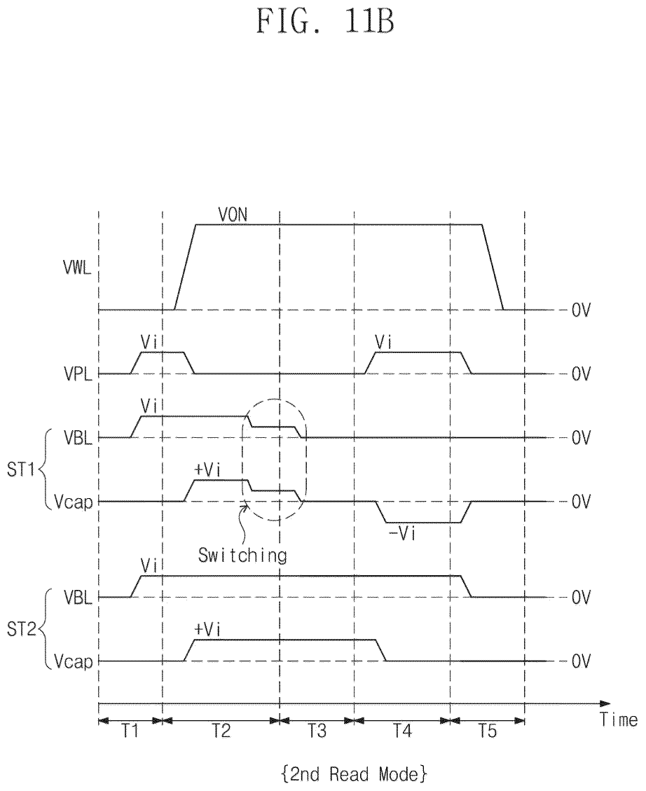

FIGS. 11A and 11B are timing diagrams for describing an operation of a memory device of FIG. 1. In FIGS. 11A and 11B, the horizontal axis represents a time, and the vertical axis represents a word line voltage VWL, the plate line voltage VPL, the bit line voltage VBL, and the across voltage Vcap of a ferroelectric capacitor. Below, for convenience, the description will be given as an internal voltage Vi or a level corresponding to the internal voltage Vi is applied as the plate line voltage VPL, the bit line voltage VBL, and the across voltage Vcap. However, the present disclosure is not limited thereto. For example, a voltage level which is applied as the plate line voltage VPL, the bit line voltage VBL, and the across voltage Vcap may be variously changed.

Referring to FIG. 11A, the read operation of the memory device 100 based on the first read mode RM1 will be described. Referring to FIGS. 1, 2, 6, and 11A, in a first time period T1, the memory device 100 may receive a read command from the external device (e.g., a controller). In an example embodiment, the read command may include an activation command (ACT) defined by the DDR interface. During the first time period T1, the word line voltage VWL, the plate line voltage VPL, and the bit line voltage VBL may maintain 0 V.

In a second time period T2, the memory device 100 may perform a charge sharing operation. For example, in the second time period T2, in response to the read command, the memory device 100 may apply the on voltage VON to the word line voltage VWL and may increase the plate line voltage VPL to the internal voltage Vi. In this case, the across voltage Vcap may change to a level of a negative internal voltage −Vi. In an example embodiment, the negative internal voltage −Vi may correspond to the first read voltage VRD1 described above.

Because the across voltage Vcap is the negative internal voltage −Vi, the polarization state of the ferroelectric capacitor FC of the memory cell MC may have the negative saturation polarization state −Prm. In this case, assuming that the ferroelectric capacitor FC of the memory cell MC has the first state ST1, because the across voltage Vcap is the negative internal voltage −Vi, the polarization state of the ferroelectric capacitor FC of the memory cell MC may not be switched. That is, the direction of the polarization state of the ferroelectric capacitor FC is not changed. Accordingly, in the second time period T2, the across voltage Vcap may maintain the level of the negative internal voltage −Vi, and the bit line voltage VBL may maintain 0V.

In contrast, assuming that the ferroelectric capacitor FC of the memory cell MC has the second state ST2, because the across voltage Vcap is the negative internal voltage −Vi, the polarization state of the ferroelectric capacitor FC of the memory cell MC may be switched. That is, the direction of the polarization state is changed. Accordingly, in the second time period T2, the across voltage Vcap may increase to 0 V, and the bit line voltage VBL may increase to the level of the internal voltage Vi.

In a third time period T3, the memory device 100 may perform a sensing operation. For example, through the operation in the second time period T2, in the third time period T3, the bit line voltage VBL connected to the memory cell MC of the first state ST1 may be 0 V, and the bit line voltage VBL connected to the memory cell MC of the second state ST2 may be the internal voltage Vi. In the third time period T3, the memory device 100 may compare the bit line voltage VBL and the reference voltage VREF to determine whether the memory cell MC is in the first state ST1 or the second state ST2. In a fourth time period T4, the memory device 100 may perform the rewrite operation. For example, in the fourth time period T4, the memory device 100 may decrease the plate line voltage VPL to 0 V. In this case, the across voltage Vcap may change to 0 V or the level of the internal voltage Vi by the plate line voltage VPL of 0 V.

As an example, when the memory cell MC is in the first state ST1, in the fourth time period T4, the bit line voltage VBL may be 0 V, and thus, the across voltage Vcap is changed to 0 V by the plate line voltage VPL of 0 V. Because the ferroelectric capacitor FC of the memory cell MC has the negative saturation polarization state −Prm by the charge sharing operation, in response to the across voltage Vcap being 0 V, the ferroelectric capacitor FC of the memory cell MC may have the first polarization state −Pr1. That is, the memory cell MC may be rewritten to the first state ST1 (i.e., an original state).

Alternatively, when the memory cell MC is in the second state ST2, in the fourth time period T4, the bit line voltage VBL is the internal voltage Vi, and thus, the across voltage Vcap is changed to the internal voltage +Vi by the plate line voltage VPL of 0 V. In response to the across voltage Vcap being the internal voltage +Vi, the ferroelectric capacitor FC of the memory cell MC may have the positive saturation polarization state +Prm; afterwards, through an operation in a fifth time period T5, the ferroelectric capacitor FC of the memory cell MC may have the second polarization state +Pr2. That is, the memory cell MC may be rewritten to the second state ST2 (i.e., an original state).

In the fifth time period T5, the memory device 100 may perform a precharge operation. For example, in the fifth time period T5, the memory device 100 may maintain the plate line voltage VPL and the bit voltage VPL at 0 V. In this case, the across voltage Vcap may be of 0 V. In an example embodiment, as the across voltage Vcap is of 0 V, the polarization state of the ferroelectric capacitor FC of the memory cell MC may be stabilized (i.e., may have the first polarization state −Pr1 or the second polarization state +Pr2). After the precharge operation is completed, the memory device 100 may decrease the word line voltage VWL to 0 V.

Referring to FIG. 11B, the read operation of the memory device 100 based on the second read mode RM2 will be described. Referring to FIGS. 1, 2, 6, and 11B, in the first time period T1, the memory device 100 may receive a read command from the external device (e.g., a controller). In an example embodiment, the read command may include the active command (ACT) defined by the DDR interface. In the first time period T1, the memory device 100 may increase the plate line voltage VPL and the bit voltage VPL to the internal voltage Vi.

In the second time period T2, the memory device 100 may perform the charge sharing operation. For example, in the second time period T2, in response to the read command, the memory device 100 may apply the on voltage VON to the word line voltage VWL and may decrease the plate line voltage VPL to 0 V. In this case, the across voltage Vcap may change to the level of the internal voltage +Vi. In an example embodiment, the internal voltage +Vi may correspond to the second read voltage VRD2 described above.

Because the across voltage Vcap is the internal voltage +Vi, the polarization state of the ferroelectric capacitor FC of the memory cell MC may have the positive saturation polarization state +Prm. In this case, assuming that the ferroelectric capacitor FC of the memory cell MC has the first state ST1, because the across voltage Vcap is the internal voltage Vi, the polarization state of the ferroelectric capacitor FC of the memory cell MC is switched. That is, the direction of the polarization state of the ferroelectric capacitor FC is changed. Accordingly, in the second time period T2, the across voltage Vcap may decrease to 0 V, and the bit line voltage VBL may decrease to 0V.

In contrast, assuming that the ferroelectric capacitor FC of the memory cell MC has the second state ST2, because the across voltage Vcap is the internal voltage +Vi, the polarization state of the ferroelectric capacitor FC of the memory cell MC is not switched. That is, the direction of the polarization state of the ferroelectric capacitor FC is not changed. Accordingly, in the second time period T2, the across voltage Vcap may maintain the level of the internal voltage +Vi, and the bit line voltage VBL may maintain the internal voltage Vi.

In the third time period T3, the memory device 100 may perform the sensing operation. For example, through the operation in the second time period T2, in the third time period T3, the bit line voltage VBL connected to the memory cell MC of the first state ST1 may be 0 V, and the bit line voltage VBL connected to the memory cell MC of the second state ST2 may be the internal voltage Vi. In the third time period T3, the memory device 100 may compare the bit line voltage VBL and the reference voltage VREF to determine whether the memory cell MC is in the first state ST1 or the second state ST2.

In the fourth time period T4, the memory device 100 may perform the rewrite operation. For example, in the fourth time period T4, the memory device 100 may increase the plate line voltage VPL to the internal voltage Vi. In this case, the across voltage Vcap may change to 0 V or the negative internal voltage −Vi by the plate line voltage VPL of the internal voltage Vi.

As an example, when the memory cell MC is in the first state ST1, in the fourth time period T4, the bit line voltage VBL is 0 V, and thus, the across voltage Vcap is changed to the negative internal voltage −Vi by the plate line voltage VPL of the internal voltage Vi. Because the ferroelectric capacitor FC of the memory cell MC has the positive saturation polarization state +Prm by the charge sharing operation, in response to the across voltage Vcap being the negative internal voltage −Vi, the ferroelectric capacitor FC of the memory cell MC may have the negative saturation polarization state −Prm; afterwards, through an operation in the fifth time period T5, the ferroelectric capacitor FC of the memory cell MC may have the first polarization state −Pr1. That is, the memory cell MC may be rewritten to the first state ST1 (i.e., an original state). Alternatively, when the memory cell MC is in the second state ST2, in the fourth time period T4, the bit line voltage VBL is the internal voltage Vi, and thus, the across voltage Vcap is changed to 0 V by the plate line voltage VPL of 0 V. In response to the across voltage Vcap being 0 V, the ferroelectric capacitor FC of the memory cell MC may have the second polarization state +Pr2. That is, the memory cell MC may be rewritten to the second state ST2 (i.e., an original state).

In the fifth time period T5, the memory device 100 may perform the precharge operation. For example, in the fifth time period T5, the memory device 100 may maintain the plate line voltage VPL and the bit voltage VPL at 0 V. In this case, the across voltage Vcap may be of 0 V. In an example embodiment, as the across voltage Vcap is of 0 V, the polarization state of the ferroelectric capacitor FC of the memory cell MC may be stabilized (i.e., may have the first polarization state −Pr1 or the second polarization state +Pr2). After the precharge operation is completed, the memory device 100 may decrease the word line voltage VWL to 0 V.

The timing diagrams of FIGS. 11A and 11B are provided as a partial example of the read operation of the memory device 100 according to an example embodiment, and example embodiments are not limited thereto. For example, voltage levels or biases which are used in each read operation may be variously changed and modified.

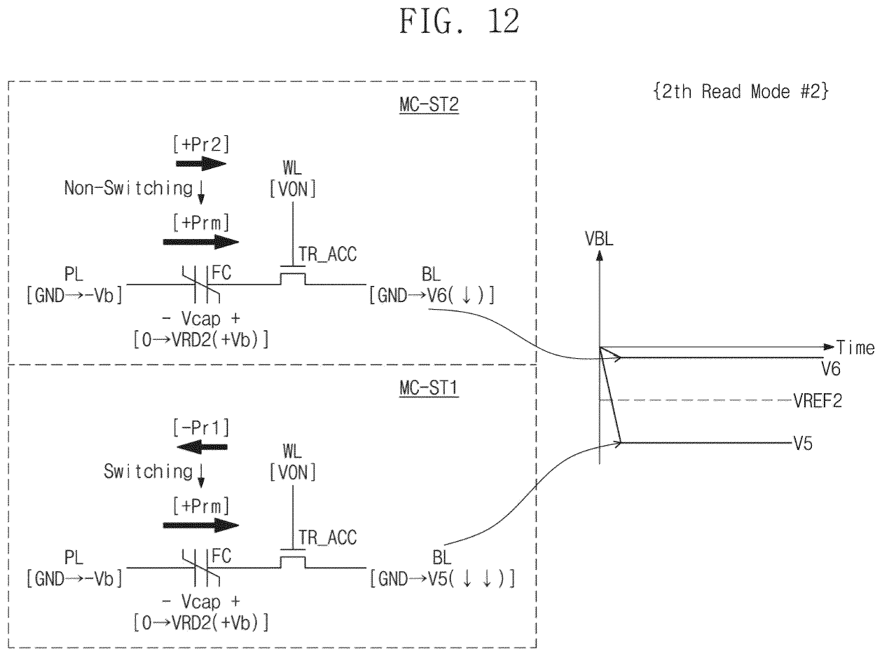

FIG. 12 is a diagram for describing a read operation based on a second read mode of FIG. 5. In the above example embodiment, polarities of the read voltages VRD1 and VRD2 which are applied as the across voltage Vcap of the ferroelectric capacitor FC in the first and second read modes RM1 and RM2 are different from each other, but the state of the memory cell MC is determined by using the same reference voltage VREF. However, the present disclosure is not limited thereto.

For example, as illustrated in FIG. 12, in the second read mode RM2, the memory device 100 may apply the ground voltage GND to the plate line PL and the bit line BL and may then apply −Vb (i.e., a negative voltage) to the plate line PL. In this case, the across voltage Vcap of the ferroelectric capacitor FC may change to the second read voltage VRD2 (i.e., +Vb). The operation principle of FIG. 12 is similar to the above operation principle except that a negative voltage is applied to the plate line PL, and thus, additional description will be omitted to avoid redundancy.

In this case, the voltage of the bit line BL of the first state memory cell MC-ST1 may decrease from the ground voltage GND to a fifth voltage V5, and the voltage of the bit line BL of the second state memory cell MC-ST2 may decrease from the ground voltage GND to a sixth voltage V6. The memory device 100 may determine states of memory cells based on a second reference voltage VREF2. For example, when the bit line voltage VBL is higher than the second reference voltage VREF2 (e.g., V6), the memory device 100 may determine that a memory cell is in the second state ST2; when the bit line voltage VBL is lower than the second reference voltage VREF2 (e.g., V5), the memory device 100 may determine that a memory cell is in the first state ST1.

In an example embodiment, in the second read mode RM2 discussed with reference to FIG. 12, the memory device 100 may perform the rewrite operation by changing the voltage of the plate line PL from −Vb to the ground voltage GND. The principle of the rewrite operation is similar to the above principle except that the voltage level of the plate line PL described with reference to FIG. 12 is different from that described above, and thus, additional description will be omitted to avoid redundancy.

As described above, the memory device 100 may perform the read operation on the memory cells MC, based on the first and second read modes RM1 and RM2. In this case, the first read voltage VRD1 used as the across voltage Vcap of the ferroelectric capacitor FC in the first read mode RM1 and the second read voltage VRD2 used as the across voltage Vcap of the ferroelectric capacitor FC in the second read mode RM2 may have opposite polarities. For example, the first read voltage VRD1 may be a negative voltage or a positive voltage, the second read voltage VRD2 may be a positive voltage or a negative voltage. In this case, the memory device 100 may variously control the voltages of the plate line PL and the bit line BL such that the first and second read voltages VRD1 and VRD2 are applied, and thus, the memory device 100 may determine states of memory cells by using various reference voltages.

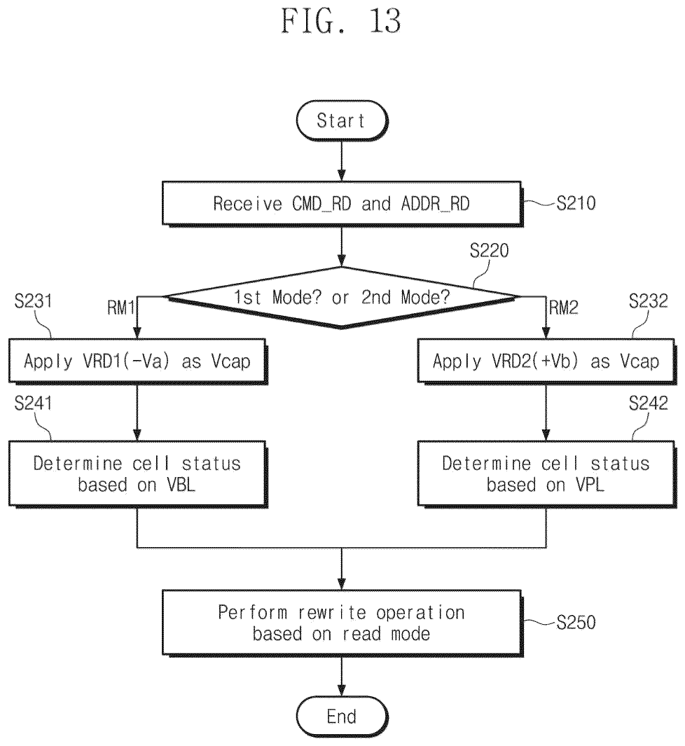

FIG. 13 is a flowchart illustrating an operation of a memory device of FIG. 1. For convenience of description, additional description associated with the components described above will be omitted to avoid redundancy. Referring to FIGS. 1 and 13, the memory device 100 may perform operation S210 and operation S220. Operation S210 and operation S220 are similar to operation S110 and operation S120 of FIG. 5, and thus, additional description will be omitted to avoid redundancy.

When the read mode is the first read mode RM1, in operation S231, the memory device 100 may apply the first read voltage VRD1 as the across voltage Vcap of the ferroelectric capacitor FC. In operation S241, the memory device 100 may determine a state of a memory cell based on the bit line voltage VBL. In an example embodiment, operation S231 and operation S241 (i.e., the operation in the first read mode RM1) is similar those described with reference to FIGS. 7A and 7B, and thus, additional description will be omitted to avoid redundancy.

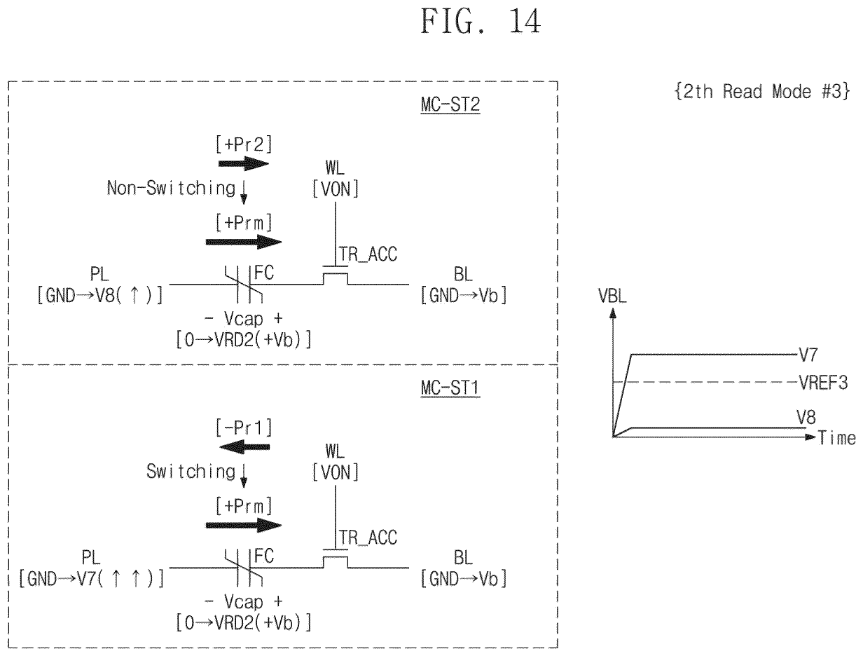

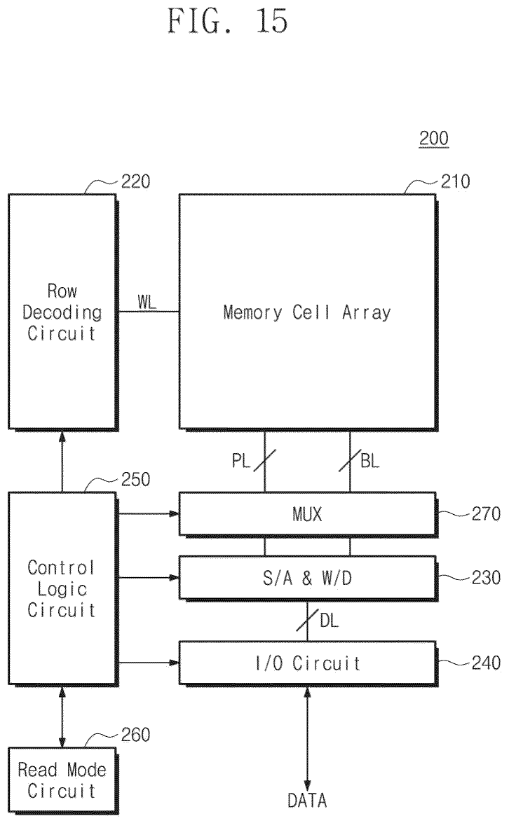

When the read mode is the second read mode RM2, in operation S232, the memory device 100 may apply the second read voltage VRD2 as the across voltage Vcap of the ferroelectric capacitor FC. In operation S242, the memory device 100 may determine a state of a memory cell based on the plate line voltage VPL. For example, in the second read mode RM2 described above, the memory device 100 may control the voltage of the plate line PL such that the second read voltage VRD2 is applied as the across voltage Vcap and may determine the state of the memory cell based on the bit line voltage VBL. In contrast, as discussed with reference to FIG. 13, in the second read mode RM2, the memory device 100 may control the voltage of the bit line voltage VBL such that the second read voltage VRD2 is applied as the across voltage Vcap and may determine the state of the memory cell based on the plate line voltage VPL. Operation S232 and operation S242 will be described in detail with reference to FIGS. 14 and 15.

In operation S250, the memory device 100 may perform the rewrite operation based on the read mode. For example, when the memory device 100 operates in the first read mode RM1, the memory device 100 may control the plate line voltage VPL to perform the rewrite operation on the memory cell. This is similar to that described with reference to FIGS. 9A and 9B, and thus, additional description will be omitted to avoid redundancy. When the memory device 100 operates in the second read mode RM2, the memory device 100 may control the bit line voltage VBL to perform the rewrite operation on the memory cell. For example, in the second read mode RM2, the memory device 100 may control the bit line voltage VBL such that the second read voltage VRD2 is applied as the across voltage Vcap. In this case, the voltage of the plate line voltage VPL may change due to the change in the polarization state of the ferroelectric capacitor FC. Accordingly, the memory device 100 may again control the bit line voltage VBL such that the polarization state of the ferroelectric capacitor FC has an original state, that is, may perform the rewrite operation such that the polarization state of the ferroelectric capacitor FC has an original state. The principle of the rewrite operation in the second read mode RM2 is similar to the above principle except that not the plate line voltage VPL but the bit line voltage VBL is controlled, and thus, additional description will be omitted to avoid redundancy.

FIG. 14 is a diagram for describing an operation according to a second read mode of FIG. 13. Referring to FIGS. 1, 13, and 14, in the second read mode RM2, the memory device 100 may maintain the plate line PL and the bit line BL with the ground voltage GND. In this case, the across voltage Vcap of the ferroelectric capacitor FC is 0 V, the ferroelectric capacitor FC of the first state memory cell MC-ST1 has the first polarization state −Pr1, and the ferroelectric capacitor FC of the second state memory cell MC-ST2 has the second polarization state +Pr2. The memory device 100 may change the voltage of the bit line BL from the ground voltage GND to Vb, and thus, the across voltage Vcap of the ferroelectric capacitor FC may change from 0 V to the second read voltage VRD2 (i.e., +Vb). According to this bias condition, as in the above description, the polarization state of the ferroelectric capacitor FC may change to the positive saturation polarization state +Prm.

In this case, the voltage VPL of the plate line PL connected to the first state memory cell MC-ST1 may increase to a seventh voltage V7, and the voltage VPL of the plate line PL connected to the second state memory cell MC-ST2 may increase to an eighth voltage V8. As in the above description, a change amount of the plate line voltage VPL may correspond to a change amount of the polarization state or whether switching is made. The polarization state of the first state memory cell MC-ST1 may change from the first polarization state −Pr1 to the positive saturation polarization state +Prm; in this case, the change amount of the polarization state may be ΔPr_c, and the polarization state is switched. The polarization state of the second state memory cell MC-ST2 may change from the second polarization state +Pr2 to the positive saturation polarization state +Prm; in this case, the change amount of the polarization state may be ΔPr_d, and the polarization state is not switched. That is, ΔPr_c is greater than ΔPr_d. That is, in the second read mode RM2, the change amount (or the increment) of the plate line voltage VPL associated with the first state memory cell MC-ST1 is greater than the change amount (or the increment) of the plate line voltage VPL associated with the second state memory cell MC-ST2. In this regard, the seventh voltage V7 may be higher than the eighth voltage V8.

In the second read mode RM2, the memory device 100 may determine a state of a memory cell based on the plate line voltage VPL. For example, when the plate line voltage VPL is higher than a third reference voltage VREF3 (e.g., V7), the memory device 100 may determine that a memory cell is in the first state ST1; when the plate line voltage VPL is lower than the third reference voltage VREF3 (e.g., V8), the memory device 100 may determine that a memory cell is in the second state ST2.

FIG. 15 is a block diagram illustrating a memory device performing an operation according to the flowchart of FIG. 13. Referring to FIG. 15, a memory device 200 may include a memory cell array 210, a row decoding circuit 220, a sense amplifier/write driver 230, an input/output circuit 240, a control logic circuit 250, and a read mode circuit 260. The memory cell array 210, the row decoding circuit 220, the sense amplifier/write driver 230, the input/output circuit 240, the control logic circuit 250, and the read mode circuit 260 are similar to those described with reference to FIG. 1, and thus, additional description will be omitted to avoid redundancy.

In an example embodiment, the memory device 200 may further include a multiplexer (MUX) circuit 270. The MUX circuit 270 may be provided between the memory cell array 210 and the sense amplifier/write driver 230. The MUX circuit 270 may be configured to switch the plurality of plate lines PL and the plurality of bit lines BL between the memory cell array 210 and the sense amplifier/write driver 230.

For example, as described with reference to FIG. 13 and FIG. 14, the memory device 200 may perform the read operation based on the first and second read modes RM1 and RM2. In the first read mode RM1, the memory device 200 may determine a state of a memory cell by controlling the plate line PL and sensing a voltage change of the bit line BL. In the second read mode RM2, the memory device 200 may determine a state of a memory cell by controlling the bit line BL and sensing a voltage change of the plate line PL.

The MUX circuit 270 may connect the bit lines PL with the sense amplifier/write driver 230 in the first read mode RM1 and may connect the plate lines PL with the sense amplifier/write driver 230 in the second read mode RM2. In this case, the sense amplifier/write driver 230 may sense voltage changes of the bit lines BL in the first read mode RM1 and may sense voltage changes of the plate lines PL in the second read mode RM2.

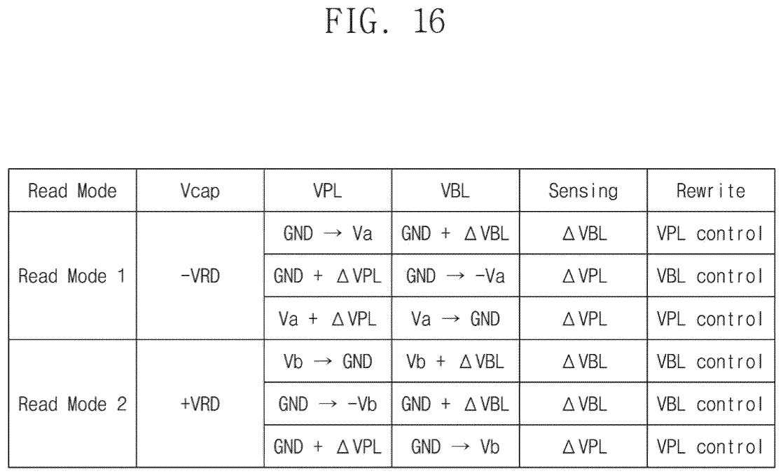

FIG. 16 is a diagram for describing first and second read modes of a memory device of FIG. 1. Referring to FIGS. 1 and 16, the memory device 100 may perform the read operation on the memory cells MC based on the first and second read modes RM1 and RM2.

In the first read mode RM1, the memory device 100 may apply the negative read voltage −VRD as the across voltage Vcap of the ferroelectric capacitor FC. For example, the across voltage Vcap of the ferroelectric capacitor FC may be expressed as a difference (i.e., VBL-VPL) between the bit line voltage VBL and the plate line voltage VPL. Accordingly, in the first read mode RM1, the memory device 100 may provide a voltage higher than the bit line voltage VBL as the plate line voltage VPL or may apply a voltage lower than the plate line voltage VPL as the bit line voltage VBL.

In detail, in the first read mode RM1, the memory device 100 may maintain the plate line voltage VPL and the bit line voltage VBL at the ground voltage GND and may then increase the plate line voltage VPL to the ground voltage GND to Va. In this case, the bit line voltage VBL may change to (GND+ΔVBL) depending on a state of a memory cell or a polarization state of a ferroelectric capacitor. The memory device 100 may sense the change amount ΔVBL of the bit line voltage VBL to determine the state of the memory cell and may control the plate line voltage VPL to perform the rewrite operation. As an example, the memory device 100 may perform the rewrite operation by changing the plate line voltage VPL to the ground voltage GND.

Alternatively, in the first read mode RM1, the memory device 100 may maintain the plate line voltage VPL and the bit line voltage VBL at the ground voltage GND and may then decrease the plate line voltage VPL to the ground voltage GND to −Va. In this case, the plate line voltage VPL may change to (GND+ΔVPL) depending on a state of a memory cell or a polarization state of a ferroelectric capacitor. The memory device 100 may sense the change amount ΔVPL of the plate line voltage VBL to determine the state of the memory cell and may control the bit line voltage VBL to perform the rewrite operation. As an example, the memory device 100 may perform the rewrite operation by changing the bit line voltage VBL to the ground voltage GND.

Alternatively, in the first read mode RM1, the memory device 100 may maintain the plate line voltage VPL and the bit line voltage VBL at Va and may then decrease the bit line voltage VBL to Va to the ground voltage GND. In this case, the plate line voltage VPL may change to (Va+ΔVPL) depending on a state of a memory cell or a polarization state of a ferroelectric capacitor. The memory device 100 may sense the change amount ΔVPL of the plate line voltage VBL to determine the state of the memory cell and may control the bit line voltage VBL to perform the rewrite operation. As an example, the memory device 100 may perform the rewrite operation by changing the bit line voltage VBL to Va.

In the second read mode RM2, the memory device 100 may apply the positive read voltage +VRD as the across voltage Vcap of the ferroelectric capacitor FC. For example, the across voltage Vcap of the ferroelectric capacitor FC may be expressed as a difference (i.e., VBL-VPL) between the bit line voltage VBL and the plate line voltage VPL. Accordingly, in the second read mode RM2, the memory device 100 may provide a voltage lower than the bit line voltage VBL as the plate line voltage VPL or may apply a voltage higher than the plate line voltage VPL as the bit line voltage VBL.

In detail, in the second read mode RM2, the memory device 100 may maintain the plate line voltage VPL and the bit line voltage VBL at Vb and may then decrease the plate line voltage VPL to Vb to the ground voltage GND. In this case, the bit line voltage VBL may change to (Vb +ΔVBL) depending on a state of a memory cell or a polarization state of a ferroelectric capacitor. The memory device 100 may sense the change amount ΔVBL of the bit line voltage VBL to determine the state of the memory cell and may control the plate line voltage VPL to perform the rewrite operation. As an example, the memory device 100 may perform the rewrite operation by changing the plate line voltage VPL to Vb.

Alternatively, in the second read mode RM2, the memory device 100 may maintain the plate line voltage VPL and the bit line voltage VBL at the ground voltage GND and may then decrease the plate line voltage VPL to −Vb. In this case, the bit line voltage VBL may change to (GND+ΔVBL) depending on a state of a memory cell or a polarization state of a ferroelectric capacitor. The memory device 100 may sense the change amount ΔVBL of the bit line voltage VBL to determine the state of the memory cell and may control the plate line voltage VPL to perform the rewrite operation. As an example, the memory device 100 may perform the rewrite operation by changing the plate line voltage VPL to the ground voltage GND.

Alternatively, in the second read mode RM2, the memory device 100 may maintain the bit voltage VPL and the bit line voltage VBL at the ground voltage GND, and may then increase the bit line voltage VBL from the ground voltage GND to Vb. In this case, the plate line voltage VPL may change to (GND+ΔVPL) depending on a state of a memory cell or a polarization state of a ferroelectric capacitor. The memory device 100 may sense the change amount A VPL of the plate line voltage VPL to determine the state of the memory cell and may control the bit line voltage VBL to perform the rewrite operation. As an example, the memory device 100 may perform the rewrite operation by changing the bit line voltage VBL to the ground voltage GND.

Above, various voltages (e.g., Va, Vb, VRD1, VRD2, VTG1, and VTG2) are described, but the present disclosure is not limited thereto. For example, the absolute values of the various voltages (e.g., Va, Vb, VRD1, VRD2, VTG1, and VTG2) may have similar levels or may have a level corresponding to a power supply voltage VCC. As described above, the various voltages may have different levels and may have an appropriate voltage corresponding to each operation.

As described above, the memory device 100 may variously control the plate line voltage VPL and the bit line voltage VBL depending on the first read mode RM1 or the second read mode RM2. In this case, the memory device 100 may apply the read voltages −VRD and +VRD of different polarities as the across voltage Vcap of the ferroelectric capacitor FC of the memory cell MC depending on the read mode, and thus, the imprint phenomenon capable of occurring at the ferroelectric capacitor FC may be prevented. Accordingly, the reliability of the memory device 100 may be improved.

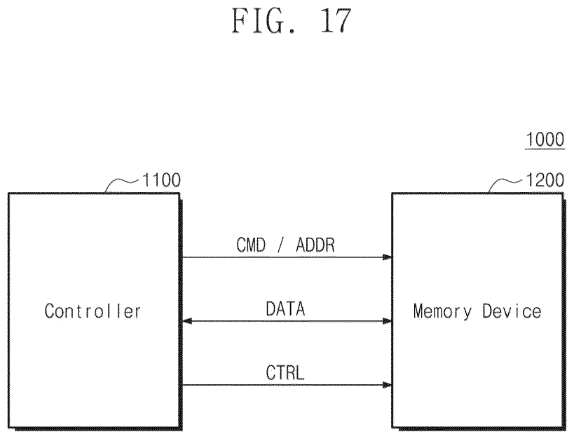

FIG. 17 is a block diagram illustrating a memory system according to an example embodiment. Referring to FIG. 17, a system 1000 may include a controller 1100 and a memory device 1200. The controller 1100 may be configured to control the memory device 1200. For example, the controller 1100 may transmit the command CMD and the address ADDR to the memory device 1200, and may exchange data “DATA” with the memory device 1200. The controller 1100 may provide the memory device 1200 with various control signals CTRL to control the memory device 1200.

The controller 1100 may be a central processing unit (CPU) or an application processor (AP) configured to control all the operations of the system 1000 or may be included therein. In an example embodiment, the controller 1100 may communicate with the memory device 520, based on the DDR interface. However, the present disclosure is not limited thereto. For example, the controller 510 may communicate with the memory device 1200 through various interfaces such as an ATA interface, an SATA interface, an e-SATA interface, an SCSI interface, an SAS interface, a PCI interface, a PCIe interface, an NVMe interface, an IEEE 1394 interface, an USB interface, an SD card interface, an MMC interface, an eMMC interface, an UFS interface, an eUFS interface, and a CF card interface.

In an example embodiment, the memory device 1200 may be the memory device 100 or 200 described with reference to FIGS. 1 to 16 or may operate based on the operation method described with reference to FIGS. 1 to 16.

In an example embodiment, the memory device 1200 may perform the read operation based on the first read mode RM1 or the second read mode RM2. In this case, the first and second read modes RM1 and RM2 of the memory device 1200 may be set or changed through various methods. Operations in which the read mode is set, changed, or managed in the memory device 1200 will be described with reference to the following drawings.

Below, for convenience of description, example embodiments will be described based on a configuration in which the read mode of the memory device 1200 is determined or changed, but the present disclosure is not limited thereto. For example, the read mode may be set or managed to or in the memory device 1200. Alternatively, the read mode may be set or managed individually in units of memory cell array, in units of sub-array, in units of word line, in units of data codeword, or in units of group of memory cells determined in advance. For example, the memory device 1200 may perform the read operation on first memory cells based on the first read mode RM1 and may perform the read operation on second memory cells based on the second read mode RM2. In this case, when the read mode is changed, the memory device 1200 may perform the read operation on the first memory cells based on the second read mode RM2 and may perform the read operation on the second memory cells based on the first read mode RM1.

FIG. 18 is a flowchart illustrating an operation of a memory device of FIG. 17. Referring to FIGS. 17 and 18, in operation S1100, the memory device 1200 may be powered on. For example, the memory device 1200 may receive a power from the controller 1100 or a separate power management circuit and may be powered on in response to the received power. Alternatively, the memory device 1200 may receive a power-on signal from the controller 1100.

In operation S1110, the memory device 1200 may perform an initialization operation. For example, the memory device 1200 may perform the initialization operation under control of the controller 1100. Through the initialization operation, the memory device 1200 may set various parameters for communication with the controller 1100 or may set various parameters necessary for the memory device 1200 to operate.

In operation S1120, the memory device 1200 may set the read mode to the first read mode RM1. For example, the memory device 1200 may include the read mode circuit 160 (refer to FIG. 1). The memory device 1200 may set information about the first read mode RM1 in the read mode circuit 160. In an example embodiment, the memory device 1200 may set the read mode during the initialization operation under control of the controller 1100. Alternatively, the memory device 1200 may set the read mode without control of the controller 1100.

In operation S1130, the memory device 1200 may perform a normal operation in the first read mode RM1. For example, the memory device 1200 may perform the write operation, the read operation, etc. under control of the controller 1100. The memory device 1200 may perform the read operation based on the first read mode RM1 described with reference to FIGS. 1 to 16.

In operation S1140, the memory device 1200 may be powered off and may then be powered on or may be reset.

In operation S1150, the memory device 1200 may perform the initialization operation. Operation S1150 is similar to operation S1110, and thus, additional description will be omitted to avoid redundancy.

In operation S1160, the memory device 1200 may set the read mode to the second read mode RM2. For example, the memory device 1200 may include the read mode circuit 160 (refer to FIG. 1). The memory device 1200 may set information about the second read mode RM2 in the read mode circuit 160.

In operation S1170, the memory device 1200 may perform the normal operation in the second read mode RM2. For example, the memory device 1200 may perform the write operation, the read operation, etc. under control of the controller 1100. The memory device 1200 may perform the read operation based on the second read mode RM2 described with reference to FIGS. 1 to 16.

In an example embodiment, the read mode circuit 160 may be a portion of a mode register and may set information about the read mode in response to an explicit request such as a mode register write (MRW) command of the controller 1100 or a vendor command.

As described above, the memory device 1200 may change the read mode each time the memory device 1200 is powered on or is reset or performs the initialization operation. Accordingly, as the read mode of the memory device 1200 is changed, as described above, the imprint phenomenon capable of occurring at the ferroelectric capacitor FC included in each memory cell may be prevented.

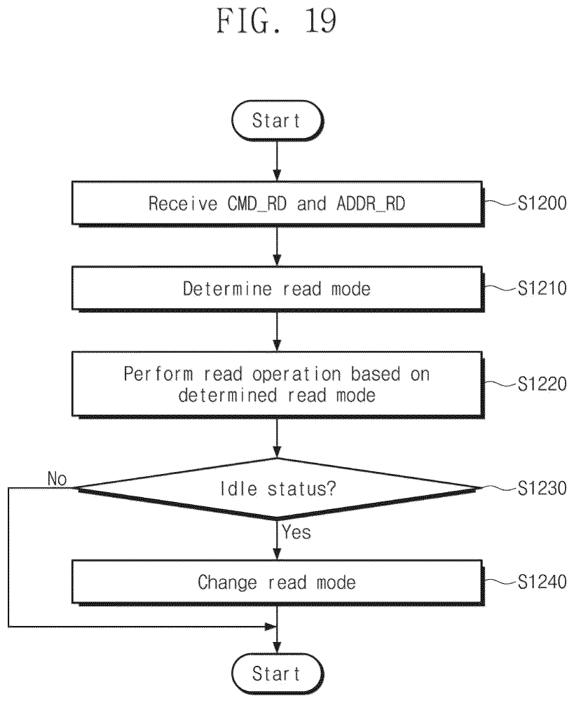

FIG. 19 is a flowchart illustrating an operation of a memory device of FIG. 17. Referring to FIGS. 17 and 19, in operation S1200, the memory device 1200 may receive the read command CMD_RD and the read address ADDR_RD. For example, the memory device 1200 may receive the read command CMD_RD and the read address ADDR_RD from the controller 1100.

In operation S1210, the memory device 1200 may determine the read mode. For example, the memory device 1200 may check information about the read mode stored in the read mode circuit 160 and may determine the read mode based on the information.

In operation S1220, the memory device 1200 may perform the read operation on memory cells corresponding to the read address ADDR based on the determined read mode. For example, when the read mode is the first read mode RM1, the memory device 1200 may perform the read operation on the memory cells corresponding to the read address ADDR based on the first read mode RM1 described with reference to FIGS. 1 to 16. Alternatively, when the read mode is the second read mode RM2, the memory device 1200 may perform the read operation based on the second read mode RM2 described with reference to FIGS. 1 to 16.

In operation S1230, the memory device 1200 may determine whether a current state is an idle state. In an example embodiment, the memory device 1200 may perform various operations under control of the controller 1100. When there is no control of the controller 1100 during a given time or when the memory device 1200 does not operate during a given time, the memory device 1200 may determine that the current state is the idle state.

When the current state is the idle state, in operation S1240, the memory device 1200 may change the read mode. For example, when the read operation in operation S1220 is performed based on the first read mode RM1, in operation S1240, the memory device 1200 may change the read mode to the second read mode RM2. The memory device 1200 may then perform the read operation based on the second read mode RM2. Alternatively, when the read operation in operation S1220 is performed based on the second read mode RM2, in operation S1240, the memory device 1200 may change the read mode to the first read mode RM1. The memory device 1200 may then perform the read operation based on the first read mode RM1.

In an example embodiment, the memory device 1200 may store information about the changed read mode in the read mode circuit 160 (refer to FIG. 1). In an example embodiment, the operation of storing the changed read mode in the read mode circuit 160 or the operation of changing the read mode may be performed under control of the controller 1100. Alternatively, the operation of storing the changed read mode in the read mode circuit 160 or the operation of changing the read mode may be performed by the memory device 1200 without control of the controller 1100.

As described above, the memory device 1200 may change the read mode during an idle time. In this case, the memory device 1200 may perform the read operation based on the first and second read modes RM1 and RM2, and thus, the reliability of the memory device 1200 may be improved.

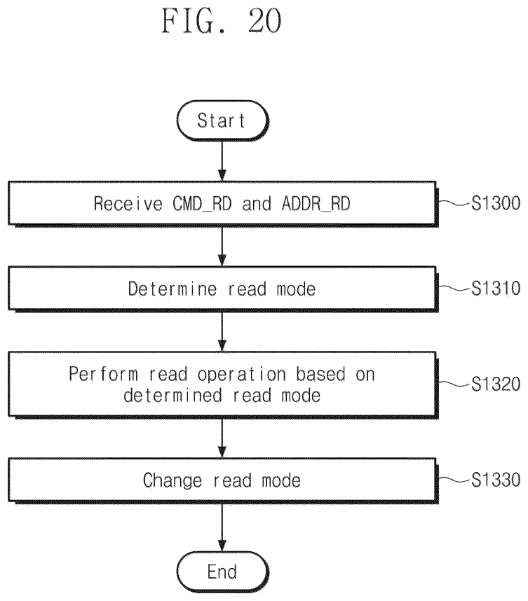

FIG. 20 is a flowchart illustrating an operation of a memory device of FIG. 17. Referring to FIGS. 17 and 20, the memory device 1200 may perform operation S1300 to operation S1320. Operation S1300 to operation S1320 are similar to operation S1200 to operation S1220 of FIG. 19, and thus, additional description will be omitted to avoid redundancy.

In operation S1330, the memory device 1200 may change the read mode. For example, when the memory device 1200 performs the read operation based on the first read mode RM1, the memory device 1200 may change a read mode to be next performed to the second read mode RM2. In this case, a subsequent read operation may be performed based on the second read mode RM2. Alternatively, when the memory device 1200 performs the read operation based on the second read mode RM2, the memory device 1200 may change a read mode to be next performed to the first read mode RM1. In this case, a subsequent read operation may be performed based on the first read mode RM1. In an example embodiment, the operation of changing the read mode is similar to that described in operation S1240 of FIG. 19, and thus, additional description will be omitted to avoid redundancy.

As described above, the memory device 1200 may change the read mode each time the read operation is performed. In this case, because the memory device 1200 performs the read operation based on the first and second read modes RM1 and RM2, the reliability of the memory device 1200 may be improved.

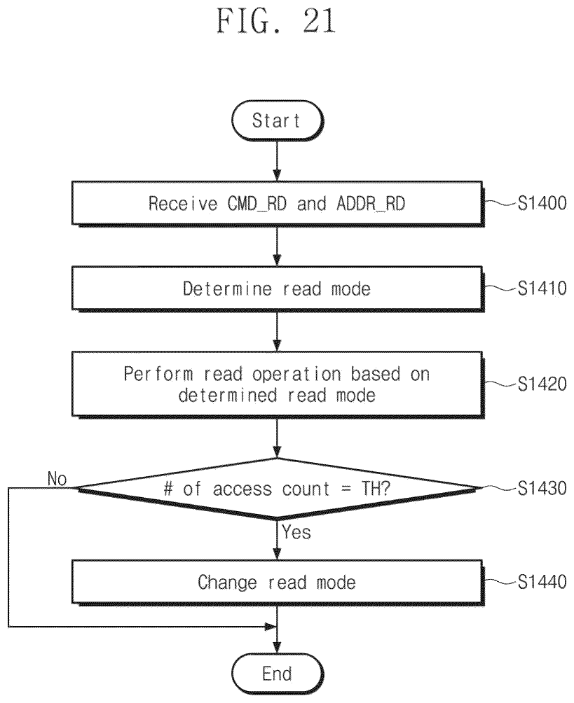

FIG. 21 is a flowchart illustrating an operation of a memory device of FIG. 17. Referring to FIGS. 17 and 21, the memory device 1200 may perform operation S1400 to operation S1420. Operation S1400 to operation S1420 are similar to operation S1200 to operation S1220 of FIG. 19, and thus, additional description will be omitted to avoid redundancy.

In operation S1430, the memory device 1200 may determine whether an access count reaches a reference value TH. For example, the memory device 1200 may manage an access count associated with memory cells. In an example embodiment, the access count may indicate the following associated with memory cells: the active number of times, the number of times of a read operation, or the number of times of write operation. In an example embodiment, the access count may be managed in units of memory cell, in units of word line, in units of codeword, in units of cache line, etc. In an example embodiment, the access count may be managed based on per row hammering tracking (PRHT) information written in dummy memory cells included in a memory cell array. The PRHT information may refer to information about the access number of times or the active number of times for each row.

When the access count reaches the reference value TH, in operation S1440, the memory device 1200 may change the read mode. The operation of changing the read mode is similar to that described in operation S1240 of FIG. 19, and thus, additional description will be omitted to avoid redundancy. When the access count reaches the reference value TH, the memory device 1200 may also reset or initialize the access count.

As described above, the memory device 1200 may change the read mode based on the access count.

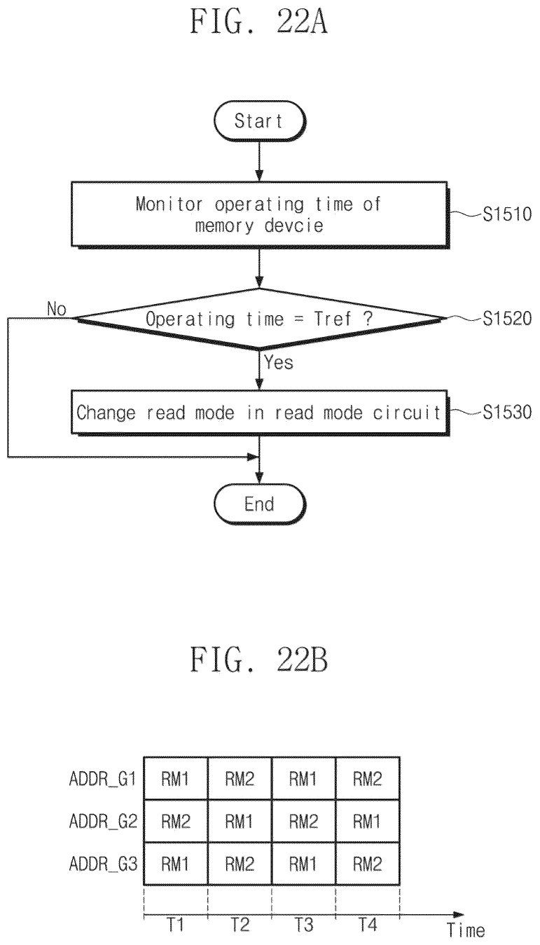

FIGS. 22A and 22B are diagrams for describing an operation of a memory device of FIG. 17. Referring to FIGS. 17, 22A, and 22B, in operation S1510, the memory device 1200 may monitor an operating time of the memory device 1200. For example, the memory device 1200 may include a timer for monitoring the operating time of the memory device 1200. In an example embodiment, the operating time of the memory device 1200 may indicate a time from a time point at which the memory device 1200 is powered on to a current time point. Alternatively, the operating time of the memory device 1200 may indicate a time from a time point at which the read mode is changed to a current time point.

In operation S1520, the memory device 1200 may determine whether the operating time reaches a reference time Tref. When the operating time reaches the reference time Tref, in operation S1530, the memory device 1200 may change the read mode. The operation of changing the read mode is similar to that described in operation S1240 of FIG. 19, and thus, additional description will be omitted to avoid redundancy.

For example, as illustrated in FIG. 22B, the memory device 1200 may manage the read mode individually for each of first to third address groups ADDR_G1 to ADDR_G3. In detail, during a first time period T1, the memory device 1200 may apply the first read mode RM1 to the first address group ADDR_G1, may apply the second read mode RM2 to the second address group ADDR_G2, and may apply the first read mode RM1 to the third address group ADDR_G3.

After the first time period T1, the memory device 1200 may change the read modes of the first to third address groups ADDR_G1 to ADDR_G3. That is, during a second time period T2 following the first time period T1, the memory device 1200 may apply the second read mode RM2 to the first address group ADDR_G1, may apply the first read mode RM1 to the second address group ADDR_G2, and may apply the second read mode RM2 to the third address group ADDR_G3.

Likewise, during a third time period T3 following the second time period T2, the memory device 1200 may change the read modes of the first to third address groups ADDR_G1 to ADDR_G3; during a fourth time period T4 following the third time period T3, the memory device 1200 may again change the read modes of the first to third address groups ADDR_G1 to ADDR_G3.

In an example embodiment, the first to third address groups ADDR_G1 to ADDR_G3 may include addresses indicating physically separated memory cells. For example, the first address group ADDR_G1 may include a plurality of first addresses indicating first memory cells, the second address group ADDR_G2 may include a plurality of second addresses indicating second memory cells, and the third address group ADDR_G3 may include a plurality of third addresses indicating third memory cells. The plurality of first memory cells, the plurality of second memory cells, and the plurality of third memory cells may be physically separated from each other or may be memory cells connected to different word lines.

As discussed with reference to FIGS. 22A and 22B, the memory device 1200 may manage read modes for three address groups ADDR_G1 to ADDR_G3, but example embodiments are not limited thereto. The memory device 1200 may manage read modes for a plurality of address groups.

As described above, the memory device 1200 may manage or change a read mode of each of a plurality of address groups, based on the operating time of the memory device 1200.

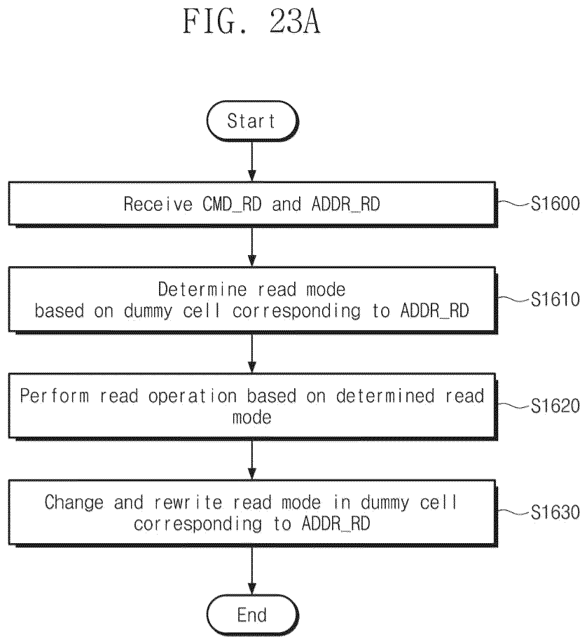

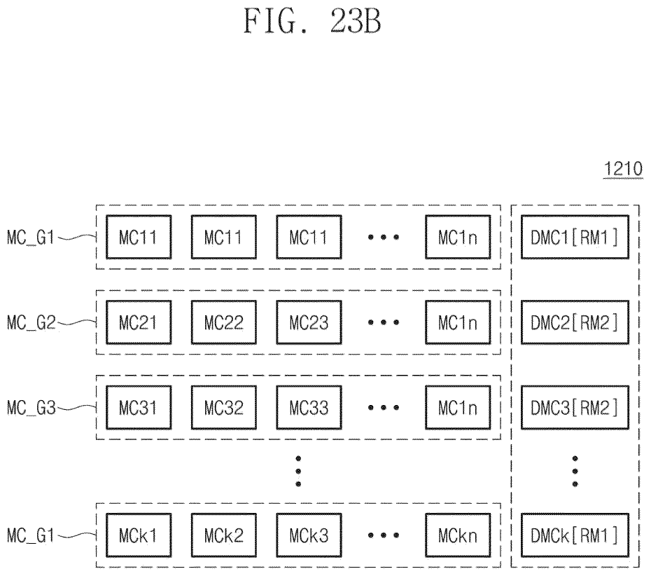

FIGS. 23A and 23B are diagrams for describing an operation of a memory device of FIG. 17. Referring to FIGS. 17, 23A, and 23B, in operation S1600, the memory device 1200 may receive the read command CMD_RD and the read address ADDR_RD from the controller 1100.

In operation S1610, the memory device 1200 may determine the read mode based on a dummy memory cell corresponding to the read address ADDR_RD. For example, as illustrated in FIG. 23B, the memory device 1200 may include a memory cell array 1210. The memory cell array 1210 may include a plurality of memory cells MC11 to MCkn and a plurality of dummy memory cells DMC1 to DMCk. In an example embodiment, each of the plurality of memory cells MC11 to MCkn and the plurality of dummy memory cells DMC1 to DMCk may be implemented with the ferroelectric memory cell described with reference to FIG. 2.

The plurality of memory cells MC11 to MCkn may be classified into a plurality of memory cell groups MC_G1 to MC_Gk. The first memory cell group MC_G1 may include the plurality of memory cells MC11 to MC1n, the second memory cell group MC_G2 may include the plurality of memory cells MC21 to MC2n, the third memory cell group MC_G3 may include the plurality of memory cells MC31 to MC3n, and the k-th memory cell group MC_Gk may include the plurality of memory cells MCk1 to MCkn.

In an example embodiment, the plurality of memory cell groups MC_G1 to MC_Gk may be classified in units of word line. For example, the memory cells MC11 to MCIn of the first memory cell group MC_G1 may be connected to at least one first word line, and the memory cells MC21 to MC2n of the second memory cell group MC_G2 may be connected to at least one second word line. In this case, the at least one first word line may be different from the at least one second word line.

In an example embodiment, the plurality of memory cell groups MC_G1 to MC_Gk may be classified in units of cache line. For example, the memory device 1200 may transmit/receive the data “DATA” to/from the controller 1100 through a plurality of data lines (e.g., DQ). In this case, the size of the data “DATA” may correspond to a cache line. The cache line may indicate the product (e.g., DQ*BL) of the number of a plurality of data lines and the number of bits output through a single data line (e.g., a burst length (BL)). The number of memory cells included in each of the plurality of memory cell groups MC_G1 to MC_Gk may correspond to the cache line (i.e., DQ*BL).

The plurality of memory cells MC11 to MCkn may be configured to store the user data. The plurality of dummy memory cells DMC1 to DMCk may be configured to store information about a read mode to be applied to the plurality of memory cells MC11 to MCkn. For example, the first dummy memory cell DMC1 may store information about a read mode to be applied to the first memory cell group MC_G1, the second dummy memory cell DMC2 may store information about a read mode to be applied to the second memory cell group MC_G2, the third dummy memory cell DMC3 may store information about a read mode to be applied to the third memory cell group MC_G3, and the k-th dummy memory cell DMCk may store information about a read mode to be applied to the k-th memory cell group MC_Gk.

In an example embodiment, the plurality of dummy memory cells DMC1 to DMCk may be connected to the same word lines as the plurality of memory cell groups MC_G1 to MC_Gk. For example, the first dummy memory cell DMC1 and the memory cells MC11 to MCIn of the first memory cell group MC_G1 may be connected to the same word line. The second dummy memory cell DMC2 and the memory cells MC21 to MC2n of the second memory cell group MC_G2 may be connected to the same word line. The third dummy memory cell DMC3 and the memory cells MC31 to MC3n of the third memory cell group MC_G3 may be connected to the same word line. The k-th dummy memory cell DMCk and the memory cells MCk1 to MCkn of the k-th memory cell group MC_Gk may be connected to the same word line.

The memory device 1200 may determine a read mode based on information stored in one dummy memory cell corresponding to the read address ADDR_RD from among the plurality of dummy memory cells DMC1 to DMCk. For example, when the read address ADDR_RD corresponds to the first memory cell group MC_G1, the memory device 1200 may check information about the first read mode RM1 stored in the first dummy memory cell DMC1 and may determine the read mode for the first memory cell group MC_G1 as the first read mode RM1. Alternatively, when the read address ADDR_RD corresponds to the second memory cell group MC_G2, the memory device 1200 may check information about the second read mode RM2 stored in the second dummy memory cell DMC2 and may determine the read mode for the second memory cell group MC_G2 as the second read mode RM2.

Returning to FIG. 23A, in operation S1620, the memory device 1200 may perform the read operation based on the determined read mode. For example, as described above, when the read address ADDR_RD corresponds to the first memory cell group MC_G1, the read mode is determined as the first read mode RM1. In this case, the memory device 1200 may perform the read operation on the first memory cell group MC_G1 based on the first read mode RM1.

In operation S1630, the memory device 1200 may change the read mode and may rewrite information about the changed read mode in the dummy memory cell DMC corresponding to the read address ADDR_RD. For example, when the read address ADDR_RD corresponds to the first memory cell group MC_G1, the read operation on the first memory cell group MC_G1 may be performed based on the first read mode RM1. In this case, the memory device 1200 may rewrite information about the second read mode RM2 in the first dummy memory cell DMC1. When the read operation on the first memory cell group MC_G1 will be performed later, the memory device 1200 may perform the read operation on the first memory cell group MC_G1 based on the second read mode RM2.

As described above, the memory device 1200 may include dummy memory cells configured to store information about a read mode. The memory device 1200 may determine the read operation based on a read mode determined based on a dummy memory cell corresponding to the read address ADDR_RD. The memory device 1200 may change the read mode and may rewrite information about the changed read mode in a dummy memory cell.

In an example embodiment, the operation of rewriting the information corresponding to the changed read mode in the dummy memory cell DMC may be performed together with or in parallel with the rewrite operation on memory cells. In an example embodiment, the operation of detecting information corresponding to the changed read mode and rewriting the information in the dummy memory cell DMC may be performed by a separate logic circuit (e.g., a read mode circuit).

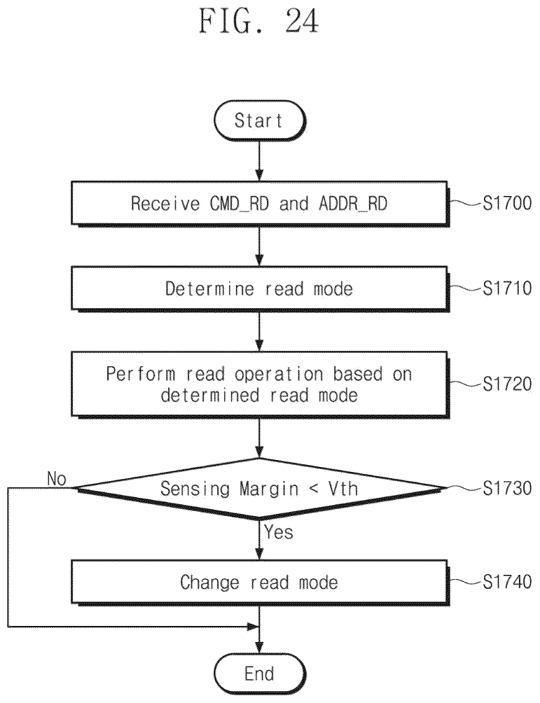

FIG. 24 is a flowchart illustrating an operation of a memory device of FIG. 17. Referring to FIGS. 17 and 24, the memory device 1200 may perform operation S1700 to operation S1720. Operation S1700 to operation S1720 are similar to operation S1200 to operation S1220 of FIG. 19, and thus, additional description will be omitted to avoid redundancy.

In operation S1730, the memory device 1200 may determine whether a sensing margin is smaller than a threshold voltage Vth. For example, as described with reference to FIGS. 1 to 16, when the memory device 1200 performs the read operation based on the first read mode RM1 or the second read mode RM2, the bit line voltage VBL or the plate line voltage VPL may vary depending on the state ST1 or ST2 of the memory cell MC, and the memory device 1200 may compare the bit line voltage VBL or the plate line voltage VPL with the reference voltage VREF to determine the state ST1 or ST2 of the memory cell MC. In this case, when the imprint phenomenon occurs at the ferroelectric capacitor FC of the memory cell MC and the memory cell MC is degraded, the sensing margin of the bit line voltage VBL or the plate line voltage VPL may decrease. This may indicate that the state of the memory cell MC is not determined normally.

In the read operation, the memory device 1200 may sense the sensing margin of the bit line voltage VBL or the plate line voltage VPL and may determine whether the sensing margin is lower than the threshold voltage Vth. In an example embodiment, the threshold voltage Vth may correspond to a sensing margin before the error of the read operation occurs due to the imprint phenomenon of the ferroelectric capacitor FC.

When the sensing margin is lower than the threshold voltage Vth, in operation S1740, the memory device 1200 may change the read mode. The operation of changing the read mode is described above, and thus, additional description will be omitted to avoid redundancy.

When the read mode is changed, the memory device 1200 may perform a subsequent read operation based on the changed read mode. In this case, because a read voltage of an opposite polarity is applied as the across voltage Vcap of the ferroelectric capacitor FC, the imprint phenomenon of the ferroelectric capacitor FC may be prevented.

As described above, in the read operation on the memory cell MC, the memory device 1200 may sense the sensing margin of the bit line voltage VBL or the plate line voltage VPL and may change the read mode, based on the sensed sensing margin.

FIG. 25 is a block diagram illustrating a memory system according to an example embodiment. Referring to FIG. 25, a memory system 2000 may include a controller 2100 and a memory device 2200. The memory system 2000, the controller 2100, and the memory device 2200 are described with reference to FIG. 17, and thus, additional description will be omitted to avoid redundancy.

As described with reference to FIGS. 1 to 24, the read mode may be managed or changed by the memory device 100, 200, or 1200. However, the present disclosure is not limited thereto. For example, the controller 2100 may include read mode logic 2110. The read mode logic 2110 may include circuitry, and may control the read mode of the memory device 2200.

For example, as in the above description given with reference to FIGS. 18 to 24, the read mode logic 2110 of the controller 2100 may manage and change the read mode of the memory device 2200 based on the operating time of the memory device 220, the operation count, the idle time, whether initialization is made, etc. In an example embodiment, the read mode logic 2110 may manage the read mode of the memory device 2200 individually in units of memory cell, in units of word line, in units of codeword, in units of cache line, in units of sub-array, etc.

The controller 2100 may control the memory device 2200 based on the read mode logic 2110 such that the memory device 2200 performs the read operation based on the first read mode RM1 or the second read mode RM2. For example, the controller 2100 may transmit a first read command CMD_RD1 and the address ADDR to the memory device 2200. The first read command CMD_RD1 may include information about the first read mode RM1. In response to the first read command CMD_RD1, the memory device 2200 may perform the read operation on memory cells corresponding to the address ADDR, based on the first read mode RM1. Alternatively, the controller 2100 may transmit a second read command CMD_RD2 and the address ADDR to the memory device 2200. The second read command CMD_RD2 may include information about the second read mode RM2. In response to the second read command CMD_RD2, the memory device 2200 may perform the read operation on memory cells corresponding to the address ADDR, based on the second read mode RM2.

As described above, the controller 2100 configured to control the memory device 2200 may be configured to manage the read mode of the memory device 2200. The memory device 2200 may receive the read command including information about the read mode from the controller 2100 and may perform the read operation based on the read mode corresponding to the received read command.

As described above, according to example embodiments, a memory device may perform the read operation on a ferroelectric memory cell based on a first read mode and a second read mode. In this case, the polarity of a first read voltage to be used in the first read mode is opposite to the polarity of a second read voltage to be used in the second read mode. As the read voltages whose polarities are opposite to each other are applied to the ferroelectric capacitor of the ferroelectric memory cell, the imprint phenomenon of the ferroelectric capacitor may be prevented. Accordingly, the reliability of the memory device may be improved.

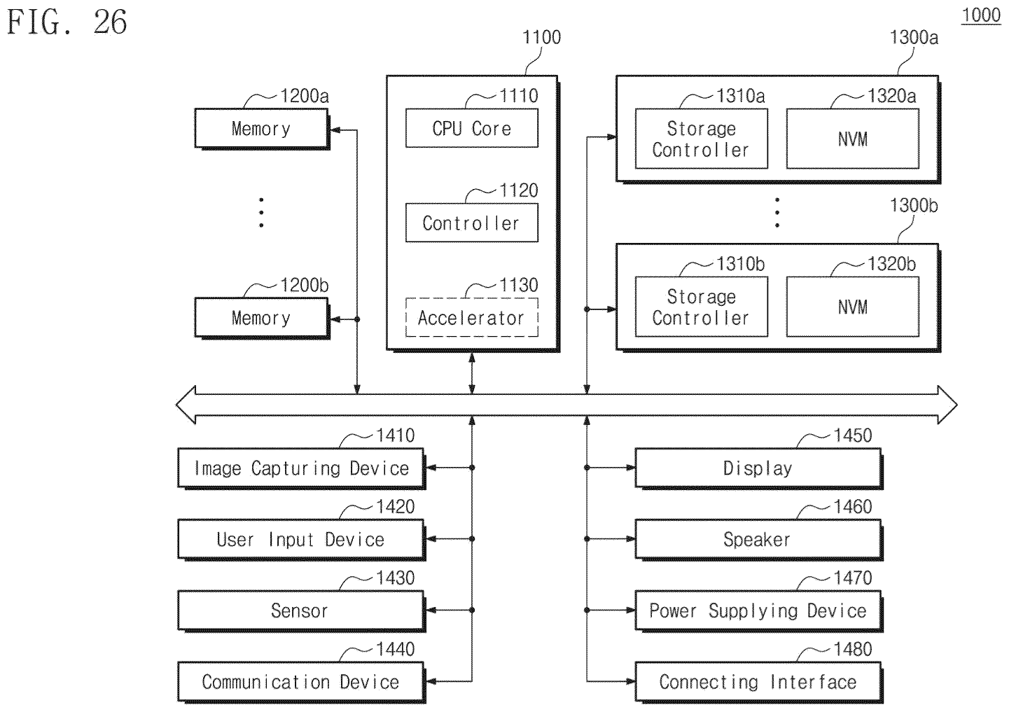

FIG. 26 is a diagram of a system 1000 to which a memory device is applied, according to an example embodiment. The system 1000 of FIG. 26 may basically be a mobile system, such as a portable communication terminal (e.g., a mobile phone), a smartphone, a tablet personal computer (PC), a wearable device, a healthcare device, or an Internet of things (IOT) device. However, the system 1000 of FIG. 26 is not necessarily limited to the mobile system and may be a PC, a laptop computer, a server, a media player, or an automotive device (e.g., a navigation device).

Referring to FIG. 26, the system 1000 may include a main processor 1100, memories (e.g., 1200a and 1200b), and storage devices (e.g., 1300a and 1300b). In addition, the system 1000 may include at least one of an image capturing device 1410, a user input device 1420, a sensor 1430, a communication device 1440, a display 1450, a speaker 1460, a power supplying device 1470, and a connecting interface 1480.

The main processor 1100 may control all operations of the system 1000, more specifically, operations of other components included in the system 1000. The main processor 1100 may be implemented as a general-purpose processor, a dedicated processor, or an application processor.

The main processor 1100 may include at least one CPU core 1110 and further include a controller 1120 configured to control the memories 1200a and 1200b and/or the storage devices 1300a and 1300b. In some example embodiments, the main processor 1100 may further include an accelerator 1130, which is a dedicated circuit for a high-speed data operation, such as an artificial intelligence (AI) data operation. The accelerator 1130 may include a graphics processing unit (GPU), a neural processing unit (NPU) and/or a data processing unit (DPU) and be implemented as a chip that is physically separate from the other components of the main processor 1100.

The memories 1200a and 1200b may be used as main memory devices of the system 1000. Although each of the memories 1200a and 1200b may include a volatile memory, such as static random access memory (SRAM) and/or dynamic RAM (DRAM), each of the memories 1200a and 1200b may include non-volatile memory, such as a flash memory, phase-change RAM (PRAM) and/or resistive RAM (RRAM). The memories 1200a and 1200b may be implemented in the same package as the main processor 1100.

The storage devices 1300a and 1300b may serve as non-volatile storage devices configured to store data regardless of whether power is supplied thereto, and have larger storage capacity than the memories 1200a and 1200b. The storage devices 1300a and 1300b may respectively include storage controllers (STRG CTRL) 1310a and 1310b and NVM(Non-Volatile Memory)s 1320a and 1320b configured to store data via the control of the storage controllers 1310a and 1310b. Although the NVMs 1320a and 1320b may include flash memories having a two-dimensional (2D) structure or a three-dimensional (3D) V-NAND structure, the NVMs 1320a and 1320b may include other types of NVMs, such as PRAM and/or RRAM.

The storage devices 1300a and 1300b may be physically separated from the main processor 1100 and included in the system 1000 or implemented in the same package as the main processor 1100. In addition, the storage devices 1300a and 1300b may have types of solid-state devices (SSDs) or memory cards and be removably combined with other components of the system 1000 through an interface, such as the connecting interface 1480 that will be described below. The storage devices 1300a and 1300b may be devices to which a standard protocol, such as a UFS, an eMMC, or an NVMe, is applied, without being limited thereto.

The image capturing device 1410 may capture still images or moving images. The image capturing device 1410 may include a camera, a camcorder, and/or a webcam.

The user input device 1420 may receive various types of data input by a user of the system 1000 and include a touch pad, a keypad, a keyboard, a mouse, and/or a microphone.

The sensor 1430 may detect various types of physical quantities, which may be obtained from the outside of the system 1000, and convert the detected physical quantities into electric signals. The sensor 1430 may include a temperature sensor, a pressure sensor, an illuminance sensor, a position sensor, an acceleration sensor, a biosensor, and/or a gyroscope sensor.

The communication device 1440 may transmit and receive signals between other devices outside the system 1000 according to various communication protocols. The communication device 1440 may include an antenna, a transceiver, and/or a modem.

The display 1450 and the speaker 1460 may serve as output devices configured to respectively output visual information and auditory information to the user of the system 1000.

The power supplying device 1470 may appropriately convert power supplied from a battery embedded in the system 1000 and/or an external power source, and supply the converted power to each of components of the system 1000.

The connecting interface 1480 may provide connection between the system 1000 and an external device, which is connected to the system 1000 and capable of transmitting and receiving data to and from the system 1000. The connecting interface 1480 may be implemented by using various interface schemes, such as ATA, SATA, e-SATA, SCSI, SAS, PCI, PCIe, NVMe, IEEE 1394, USB, SD, MMC, eMMC, UFS, eUFS, and CF.

In an example embodiment, the memory devices 1200 and 1200b may be the memory device described with reference to FIGS. 1 to 25 or may operate based on the operation method described with reference to FIGS. 1 to 25. In an example embodiment, the non-volatile memories 1320a and 1320b included in the storage device 1300a and 1300b may be the memory device described with reference to FIGS. 1 to 25 or may operate based on the operation method described with reference to FIGS. 1 to 25.

According to the present disclosure, a ferroelectric memory device may perform a read operation based on first and second read modes. The ferroelectric memory device applies a first read voltage to the ferroelectric memory cell in the first read mode and applies a second read voltage to the ferroelectric memory cell in the second read mode. The polarity of the first read voltage is opposite to the polarity of the second read voltage. In this case, because the read voltages whose polarities are opposite to each other are alternately applied to the ferroelectric memory cell, the imprint phenomenon of the ferroelectric capacitor of the ferroelectric memory cell may be prevented. Accordingly, an operation method of a memory device including a ferroelectric memory cell with improved reliability is provided.

In some example embodiments, each of the components represented by a block as illustrated in FIGS. 1, 15, 17, 23B, 25 and 26 may be implemented as various numbers of hardware and/or firmware structures that execute respective functions described above, according to example embodiments. For example, at least one of these components may include various hardware components including a digital circuit, a programmable or non-programmable logic device or array, an application specific integrated circuit (ASIC), transistors, capacitors, logic gates, or other circuitry using use a direct circuit structure, such as a memory, a processor, a logic circuit, a look-up table, etc., that may execute the respective functions through controls of one or more microprocessors or other control apparatuses. Also, at least one of these components may further include or may be implemented by a processor such as a central processing unit (CPU) that performs the respective functions, a microprocessor, or the like. Functional aspects of example embodiments may be implemented in algorithms that execute on one or more processors. Furthermore, the components, elements, modules or units represented by a block or processing steps may employ any number of related art techniques for electronics configuration, signal processing and/or control, data processing and the like.

While aspects of example embodiments have been described, it will be apparent to those of ordinary skill in the art that various changes and modifications may be made thereto without departing from the spirit and scope as set forth in the following claims.

1. A method of operating a memory device, the method comprising:
receiving a read command and an address from a controller; and
performing a read operation on a ferroelectric memory cell, in the memory device, corresponding to the address, based on a first read mode or a second read mode, in response to the read command,
wherein, in the first read mode, a first read voltage is applied as an across voltage of a ferroelectric capacitor included in the ferroelectric memory cell,
wherein, in the second read mode, a second read voltage is applied as the across voltage of the ferroelectric capacitor included in the ferroelectric memory cell, and
wherein the first read voltage and the second read voltage have opposite polarities.

2. The method of claim 1, wherein the ferroelectric memory cell further includes an access transistor provided between a first end of the ferroelectric capacitor and a bit line and configured to operate in response to a voltage of a word line, and
wherein a second end of the ferroelectric capacitor is connected to a plate line.

3. The method of claim 2, wherein the performing of the read operation comprises:
applying, in the read operation, an on-voltage to the word line;
increasing, in the first read mode, a voltage of the plate line from a ground voltage to a first voltage; and
decreasing, in the second read mode, the voltage of the plate line from a second voltage to the ground voltage,
wherein the first read voltage corresponds to a difference between the ground voltage and the first voltage, and
wherein the second read voltage corresponds to a difference between the second voltage and the ground voltage.

4. The method of claim 3, wherein the performing of the read operation further comprises comparing a voltage of the bit line with a reference voltage to determine a state of the ferroelectric memory cell.

5. The method of claim 2, wherein the performing of the read operation comprises:
applying, in the read operation, an on-voltage to the word line;
increasing, in the first read mode, a voltage of the plate line from a ground voltage to a first voltage; and
decreasing, in the second read mode, the voltage of the plate line from the ground voltage to a second voltage being a negative voltage,
wherein the first read voltage corresponds to a difference between the ground voltage and the first voltage, and
wherein the second read voltage corresponds to a difference between the second voltage and the ground voltage.

6. The method of claim 5, wherein the performing of the read operation further comprises:
comparing a voltage of the bit line with a first reference voltage to determine a state of the ferroelectric memory cell, in the first read mode; and
comparing the voltage of the bit line with a second reference voltage different from the first reference voltage to determine the state of the ferroelectric memory cell, in the second read mode.

7. The method of claim 2, further comprising:
applying, in the read operation, an on-voltage to the word line;
increasing, in the first read mode, a voltage of the plate line from a ground voltage to a first voltage; and
decreasing, in the second read mode, a voltage of the bit line from the ground voltage to a second voltage,
wherein the first read voltage corresponds to a difference between the ground voltage and the first voltage, and
wherein the second read voltage corresponds to a difference between the second voltage and the ground voltage.

8. The method of claim 7, wherein the performing of the read operation comprises:
comparing the voltage of the bit line with a first reference voltage to determine a state of the ferroelectric memory cell, in the first read mode; and
comparing the voltage of the plate line with a second reference voltage to determine a state of the ferroelectric memory cell, in the second read mode.

9. The method of claim 1, further comprising after the read operation is performed, performing a rewrite operation on the ferroelectric memory cell.

10. The method of claim 1, wherein, based on the read operation being performed based on the first read mode, a next read operation on the ferroelectric memory cell is performed based on the second read mode, and
wherein, based on the read operation being performed based on the second read mode, the next read operation on the ferroelectric memory cell is performed based on the first read mode.

11. A method of operating a memory device which includes a plurality of ferroelectric memory cells, the method comprising:
receiving a first read command and a first address from a controller;
reading data by performing a first read operation on a first ferroelectric memory cell corresponding to the first address from among the plurality of ferroelectric memory cells based on a first read voltage in response to the first read command, and outputting the data to the controller;
receiving a second read command and the first address from the controller; and
reading the data by performing a second read operation on the first ferroelectric memory cell corresponding to the first address based on a second read voltage in response to the second read command, and outputting the data to the controller,
wherein a polarity of the first read voltage is different than a polarity of the second read voltage.

12. The method of claim 11, wherein the first read operation comprises applying the first read voltage as an across voltage of a ferroelectric capacitor included in the first ferroelectric memory cell, and
wherein the second read operation comprises applying the second read voltage as the across voltage of the ferroelectric capacitor included in the first ferroelectric memory cell.

13. The method of claim 11, wherein the plurality of ferroelectric memory cells are connected to a plurality of plate lines and a plurality of bit lines, and
wherein, in each of the first read operation and the second read operation, the data are read based on a voltage change of each of the plurality of bit lines.

14. The method of claim 13, further comprising:
after the first read operation is completed, controlling a voltage of the plurality of plate lines to perform a rewrite operation on the first ferroelectric memory cell; and
after the second read operation is completed, controlling a voltage of the plurality of plate lines to perform the rewrite operation on the first ferroelectric memory cell.

15. The method of claim 11, wherein the plurality of ferroelectric memory cells are connected to a plurality of plate lines and a plurality of bit lines,
wherein the first read operation comprises reading the data based on a voltage change of each of the plurality of bit lines, and
wherein the second read operation comprises reading the data based on a voltage change of each of the plurality of plate lines.

16. A method of operating a memory device which includes a ferroelectric memory cell, the method comprising:
performing a first read operation on the ferroelectric memory cell based on a first read mode;
changing a read mode of the memory device from the first read mode to a second read mode; and
performing a second read operation on the ferroelectric memory cell based on the second read mode,
wherein the first read operation comprises applying a first read voltage as an across voltage of a ferroelectric capacitor included in the ferroelectric memory cell,
wherein the second read operation comprises applying a second read voltage as the across voltage of the ferroelectric capacitor included in the ferroelectric memory cell, and
wherein the first read voltage and the second read voltage have opposite polarities.

17. The method of claim 16, wherein the changing of the read mode of the memory device from the first read mode to the second read mode is performed based on a current state of the memory device being identified as the idle state.

18. The method of claim 16, wherein the changing of the read mode of the memory device from the first read mode to the second read mode is performed based on the first read operation being completed.

19. The method of claim 16, wherein the changing of the read mode of the memory device from the first read mode to the second read mode is performed based on an operating time of the memory device reaching a reference time.

20. The method of claim 16, further comprising after performing the second read operation on the ferroelectric memory cell, again changing the read mode of the memory device from the second read mode to the first read mode.

21-23. (canceled)
